(19) United States
(12) Patent Application Publication
(10) Pub. No.: US 2022/0307130 A1
(43) Pub. Date: Sep. 29, 2022

(54) SUBSTRATE TREATING METHOD

(71) Applicant: SCREEN HOLDINGS CO., LTD., Kyoto (JP)

(72) Inventors: Shogo Kunieda, Kyoto (JP); Yuta SASAKI, Kyoto (JP)

(21) Appl. No.: 17/578,988

(22) Filed: Jan. 19, 2022

(30) Foreign Application Priority Data
Mar. 24, 2021 (JP) 2021-050136

(51) Int. Cl. C23C 16/448; C23C 16/458; C09D 7/63

(52) U.S. Cl. CPC C23C 16/4485; C23C 16/4582; C09D 7/63

(57) ABSTRACT

Disclosed is a substrate treating method for treating a substrate. The substrate treating method includes a dehydrating step, a dispensing step (mixed liquid dispensing step), a solidified film forming step, and a sublimation step. In the dehydrating step, a mixed liquid is dehydrated. The mixed liquid contains a sublimable substance and a solvent. In the dispensing step, the mixed liquid dehydrated in the dehydrating step is dispensed onto an upper surface of the substrate. In the solidified film forming step, the solvent evaporates from the mixed liquid on the upper surface of the substrate. In the solidified film forming step, a solidified film containing the sublimable substance is formed on the upper surface of the substrate. In the sublimation step, the solidified film sublimates.

### CROSS-REFERENCE TO RELATED APPLICATIONS

This application claims priority to Japanese Patent Application No. 2021-050136 filed Mar. 24, 2021, the disclosure of which is hereby incorporated herein by reference in its entirety for all purposes.

### BACKGROUND OF THE INVENTION

### Field of the Invention

The present invention relates to a substrate treating method for performing treatment on substrates. Examples of the substrates include a semiconductor wafer, a substrate for liquid crystal display, a substrate for organic electroluminescence (EL), a substrate for flat panel display (FPD), a substrate for optical display, a magnetic disk substrate, an optical disk substrate, a magneto-optical disk substrate, a substrate for photomask, and a solar cell substrate.

### Description of the Related Art

Japanese Patent Publication No. 2021-9988A discloses a substrate treating method for drying substrates. Specifically, the substrate treating method disclosed in Japanese Patent Publication No. 2021-9988A includes a liquid film forming step, a solidified film forming step, and a sublimation step. In the liquid film forming step, a liquid film of a treatment liquid is formed on an upper surface of a substrate. The treatment liquid contains a solvent and cyclohexanone oxime. In the solidified film forming step, the solvent evaporates. In the solidified film forming step, a solidified film of the cyclohexanone oxime is formed on the upper surface of the substrate. In the sublimation step, the solidified film sublimates. The solidified film changes to gas without being a liquid. According to the substrate treating method disclosed in Japanese Patent Publication No. 2021-9988A, the substrate can be dried appropriately.

### SUMMARY OF THE INVENTION

Even with the currently-used substrate treating method, the substrate may not be dried appropriately occasionally. For example, even with the currently-used substrate treating method, a pattern formed on the upper surface of the substrate may collapse. For example, if the pattern is fine, the currently-used substrate treating method may insufficiently suppress collapse of the pattern.

The present invention has been made regarding the state of the art noted above, and its one object is to provide a substrate treating method that can dry substrates appropriately.

To overcome the above drawbacks, Inventors of the present invention have made intensive research. Firstly, the Inventors studied a reason why a substrate cannot be dried appropriately. Then, the Inventors made a guess that failure to appropriately dry the substrate is caused by water contained in the treatment liquid.

The treatment liquid contains a solvent and a sublimable substance. The solvent originally (initially) contains little water. For example, the solvent contains little water when the manufacturer ships the solvent as a product. This is because the manufacturer manages the quality of the product. For example, this is because the manufacturer controls a concentration of water in the solvent to be a specified value or less. The same is applicable to the sublimable substance. Consequently, the treatment liquid should not contain water.

Then, the Inventors reviewed the treatment liquid for use in a substrate treating method. From the review, the Inventors found that, when the treatment liquid is produced and used, the treatment liquid may take in water. When the treatment liquid is produced, the solvent and the sublimable substance are stored in a tank or flow in a pipe. When the treatment liquid is used, the treatment liquid is stored in the tank or flow in the pipe. Consequently, when the treatment liquid is produced and used, the solvent, the sublimable substance, or the treatment liquid may take in water slightly from the tank, the pipe, or air. For example, when the treatment liquid is produced and used, the solvent, the sublimable substance, or the treatment liquid may slightly take in water in the tank or the pipe. For example, when the treatment liquid is produced and used, the solvent, the sublimable substance, or the treatment liquid may slightly take in water contained in air. Then, the treatment liquid slightly containing water may be supplied to a substrate. The Inventors made a guess that failure to appropriately dry the substrate is caused by water contained in the treatment liquid when the treatment liquid is supplied to the substrate.

The present invention has been made based on the above finding through further studious consideration, and thus is constituted as stated below. One aspect of the present invention provides a substrate treating method for performing treatment on a substrate. The substrate treating method includes: a dehydrating step of dehydrating a mixed liquid containing a sublimable substance and a solvent; a dispensing step of dispensing the mixed liquid, dehydrated in the dehydrating step, onto an upper surface of the substrate; a solidified film forming step of forming a solidified film containing the sublimable substance on the upper surface of the substrate by evaporating the solvent from the mixed liquid on the upper surface of the substrate; and a sublimation step of sublimating the solidified film.

The substrate treating method includes the dehydrating step and the dispensing step. In the dehydrating step, the mixed liquid is dehydrated. The mixed liquid contains the sublimable substance and the solvent. In the dispensing step, the mixed liquid dehydrated in the dehydrating step is dispensed onto the upper surface of the substrate. Accordingly, in the dispensing step where the mixed liquid is dispensed onto the upper surface of the substrate, a concentration of water in the mixed liquid is sufficiently low.

The substrate treating method includes the solidified film forming step. In the solidified film forming step, the solvent evaporates from the mixed liquid on the upper surface of the substrate. In the solidified film forming step, the sublimable substance is deposited on the upper surface of the substrate. In the solidified film forming step, the solidified film is formed on the upper surface of the substrate. The solidified film contains the deposited sublimable substance. As described above, in the dispensing step where the mixed liquid is dispensed onto the upper surface of the substrate, the concentration of water in the mixed liquid is sufficiently low. Consequently, in the solidified film forming step, the solidified film can be formed on the upper surface of the substrate appropriately.

The substrate treating method includes the sublimation step. In the sublimation step, the solidified film sublimates. Such sublimation of the solidified film causes the solidified film to be removed from the upper surface of the substrate. As described above, in the dispensing step where the mixed liquid is dispensed onto the upper surface of the substrate, the concentration of water in the mixed liquid is sufficiently low. Consequently, in the sublimation step, the substrate can be dried appropriately.

In summary, the substrate treating method described above achieves proper drying of substrates.

It is preferred in the aspect of the substrate treating method described above that a percent concentration of mass of water contained in the mixed liquid is made 1.2 wt % or less in the dehydrating step. Accordingly, in the dispensing step where the mixed liquid is dispensed onto the upper surface of the substrate, the concentration of water in the mixed liquid is sufficiently low. Consequently, in the solidified film forming step, the solidified film can be formed on the upper surface of the substrate more appropriately. In the sublimation step, the substrate can be dried more appropriately.

It is preferred in the aspect of the substrate treating method described above that the mixed liquid is dehydrated in the dehydrating step with use of at least either an absorber configured to absorb water in the mixed liquid or a separator configured to separate water from the mixed liquid. In the dehydrating step, the mixed liquid is dehydrated suitably.

Another aspect of the present invention provides a substrate treating method for treating a substrate. The substrate treating method includes: a dehydrating step of dehydrating a first treatment liquid containing a solvent; a dispensing step of dispensing a mixed liquid, obtained by adding a sublimable substance to the first treatment liquid dehydrated in the dehydrating step, onto an upper surface of the substrate; a solidified film forming step of forming a solidified film containing the sublimable substance on the upper surface of the substrate by evaporating the solvent from the mixed liquid on the upper surface of the substrate; and a sublimation step of sublimating the solidified film.

The substrate treating method includes the dehydrating step and the dispensing step. In the dehydrating step, the first treatment liquid is dehydrated. The first treatment liquid contains the solvent. In the dispensing step, the mixed liquid is dispensed onto the upper surface of the substrate. The mixed liquid is obtained by adding the sublimable substance to the first treatment liquid, dehydrated in the dehydrating step. The mixed liquid contains the first treatment liquid dehydrated in the dehydrating step. The mixed liquid further contains the sublimable substance. Accordingly, in the dispensing step where the mixed liquid is dispensed onto the upper surface of the substrate, a concentration of water in the mixed liquid is sufficiently low.

The substrate treating method includes the solidified film forming step. In the solidified film forming step, the solvent evaporates from the mixed liquid on the upper surface of the substrate. In the solidified film forming step, the sublimable substance is deposited on the upper surface of the substrate. In the solidified film forming step, the solidified film is formed on the upper surface of the substrate. The solidified film contains the deposited sublimable substance. As described above, in the dispensing step where the mixed liquid is dispensed onto the upper surface of the substrate, the concentration of water in the mixed liquid is sufficiently low. Consequently, in the solidified film forming step, the solidified film can be formed on the upper surface of the substrate appropriately.

The substrate treating method includes the sublimation step. In the sublimation step, the solidified film sublimates. Such sublimation of the solidified film causes the solidified film to be removed from the upper surface of the substrate. As described above, in the dispensing step where the mixed liquid is dispensed onto the upper surface of the substrate, the concentration of water in the mixed liquid is sufficiently low. Consequently, in the sublimation step, the substrate can be dried appropriately.

In summary, the substrate treating method described above achieves proper drying of substrates.

It is preferred in the aspect of the substrate treating method described above that a percent concentration of mass of water contained in the first treatment liquid is made 1.2 wt % or less in the dehydrating step. Accordingly, in the dispensing step where the mixed liquid is dispensed onto the upper surface of the substrate, the concentration of water in the mixed liquid is sufficiently low. Consequently, in the solidified film forming step, the solidified film can be formed on the upper surface of the substrate more appropriately. In the sublimation step, the substrate can be dried more appropriately.

It is preferred in the aspect of the substrate treating method described above that the first treatment liquid is dehydrated in the dehydrating step with use of at least either an absorber configured to absorb water in the first treatment liquid or a separator configured to separate water from the first treatment liquid. In the dehydrating step, the first treatment liquid is dehydrated suitably.

It is preferred in the aspect of the substrate treating method described above that the mixed liquid is dispensed onto the upper surface of the substrate in the dispensing step by a dispensing unit, and that the dehydrating step is performed in either a flow path communicating with the dispensing unit or a tank communicating with the dispensing unit. The dehydrating step is performed in either the flow path communicating with the dispensing unit or the tank communicating with the dispensing unit. For example, the mixed liquid, flowing in the flow path that is in communication with the dispensing unit, is dehydrated in the dehydrating step. For example, the mixed liquid, stored in the tank that is in communication with the dispensing unit, is dehydrated in the dehydrating step. For example, the first treatment liquid, flowing in the flow path that is in communication with the dispensing unit, is dehydrated in the dehydrating step. For example, the first treatment liquid, stored in the tank that is in communication with the dispensing unit, is dehydrated in the dehydrating step. Accordingly, in the dispensing step where the mixed liquid is dispensed onto the upper surface of the substrate, the concentration of water in the mixed liquid is sufficiently low.

It is preferred in the aspect of the substrate treating method described above that the solvent contains at least one selected from chemical compounds a1) to a10) below.

a1) acetone

a2) methanol

a3) ethanol

a4) isopropyl alcohol

a5) tert-butanol

a6) 1-propanol

a7) isobutanol

a8) 1-ethoxy-2-propanol

a9) 1-butanol

a10) propylene glycol monomethyl ether acetate

This can dry the substrate appropriately.

It is preferred in the aspect of the substrate treating method described above that the sublimable substance contains at least one selected from cyclohexanone oxime, camphor, naphthalene, and ε-caprolactam. This can dry the substrate appropriately.

It is preferred in the aspect of the substrate treating method described above that dry gas is supplied to the solidified film in the sublimation step. The solidified film can be sublimated effectively in the sublimation step.

It is preferred in the aspect of the substrate treating method described above that the mixed liquid further contains a surfactant. The mixed liquid can be supplied onto the upper surface of the substrate more appropriately in the dispensing step.

It is preferred in the aspect of the substrate treating method described above that a surfactant is supplied to the substrate together with the mixed liquid in the dispensing step. The mixed liquid can be supplied onto the upper surface of the substrate more appropriately in the dispensing step.

It is preferred in the aspect of the substrate treating method described above that the first treatment liquid further contains a surfactant. The mixed liquid can be supplied onto the upper surface of the substrate more appropriately in the dispensing step.

It is preferred in the aspect of the substrate treating method described above that the surfactant has hydrophobicity. The mixed liquid can be supplied onto the upper surface of the substrate much more appropriately in the dispensing step.

It is preferred in the aspect of the substrate treating method described above that the surfactant contains at least one selected from the chemical compounds a1) to a10) (except for one contained in the solvent). The mixed liquid can be supplied onto the upper surface of the substrate much more appropriately in the dispensing step.

It is preferred in the aspect of the substrate treating method that the substrate has a pattern formed on the upper surface thereof. The substrate can be dried appropriately while the pattern is protected. For example, the substrate can be dried appropriately while collapse of the pattern is suitably suppressed.

Another aspect of the present invention provides a treatment liquid used for drying a substrate. The treatment liquid is obtained by dehydrating the mixed liquid containing a sublimable substance and a solvent.

The mixed liquid contains the sublimable substance and the solvent. The treatment liquid is obtained by dehydrating the mixed liquid. Accordingly, a concentration of water in the treatment liquid is sufficiently low. Consequently, the substrate can be dried suitably through supply of the treatment liquid to the substrate.

Another aspect of the present invention provides a treatment liquid used for drying a substrate. The treatment liquid is obtained by dehydrating a first treatment liquid containing a solvent and adding a sublimable substance to the dehydrated first treatment liquid.

The first treatment liquid contains the solvent. The treatment liquid is obtained by dehydrating the first treatment liquid and adding the sublimable substance to the dehydrated first treatment liquid. Accordingly, a concentration of water in the treatment liquid is sufficiently low. Consequently, the substrate can be dried suitably through supply of the treatment liquid to the substrate.

Another aspect of the present invention provides a substrate treating apparatus for treating a substrate. The substrate treating apparatus includes: a substrate holder configured to hold the substrate in a substantially horizontal posture; a dehydrating unit configured to dehydrate a mixed liquid containing a sublimable substance and a solvent; and a dispensing unit configured to dispense the mixed liquid, dehydrated in the dehydrating unit, onto an upper surface of the substrate held by the substrate holder.

The substrate treating apparatus includes the substrate holder, the dehydrating unit, and the dispensing unit. The substrate holder holds the substrate in a substantially horizontal posture. The mixed liquid contains the sublimable substance and the solvent. The dehydrating unit dehydrates the mixed liquid. The dispensing unit dispenses the mixed liquid, dehydrated by the dehydrating unit, onto the upper surface of the substrate held by the substrate holder. Accordingly, when the dispensing unit dispenses the mixed liquid onto the upper surface of the substrate held by the substrate holder, a concentration of water in the mixed liquid is sufficiently low. Consequently, the substrate treating apparatus can perform the substrate treating method described above suitably. That is, the substrate treating apparatus can dry the substrate appropriately.

It is preferred that the substrate treating apparatus described above further includes a first sensor configured to measure a concentration of water in the mixed liquid, and a controller configured to obtain a detection result of the first sensor. The controller can monitor the concentration of water in the mixed liquid suitably.

Another aspect of the present invention provides a substrate treating apparatus for treating a substrate. The substrate treating apparatus includes: a substrate holder configured to hold the substrate in a substantially horizontal posture; a dehydrating unit configured to dehydrate a first treatment liquid containing a solvent; and a dispensing unit configured to dispense a mixed liquid, obtained by adding a sublimable substance to the first treatment liquid dehydrated in the dehydrating unit, onto an upper surface of the substrate held by the substrate holder.

The substrate treating apparatus includes the substrate holder, the dehydrating unit, and the dispensing unit. The substrate holder holds the substrate in a substantially horizontal posture. The first treatment liquid contains the solvent. The dehydrating unit dehydrates the first treatment liquid. The dispensing unit dispenses the mixed liquid onto the upper surface of the substrate held by the substrate holder. The mixed liquid is obtained by adding the sublimable substance to the first treatment liquid dehydrated in the dehydrating unit. The mixed liquid contains the first treatment liquid dehydrated in the dehydrating unit. The mixed liquid further contains the sublimable substance. Accordingly, when the dispensing unit dispenses the mixed liquid onto the upper surface of the substrate held by the substrate holder, a concentration of water in the mixed liquid is sufficiently low. Consequently, the substrate treating apparatus can perform the substrate treating method described above suitably. That is, the substrate treating apparatus can dry the substrate appropriately.

It is preferred that the substrate treating apparatus described above further includes a first sensor configured to detect a concentration of water in the first treatment liquid, and a controller configured to obtain a detection result of the first sensor. The controller can monitor the concentration of water in the first treatment liquid suitably.

It is preferred in the substrate treating apparatus described above that the substrate has a pattern formed on the upper surface thereof when the substrate holder holds the substrate. The substrate can be treated appropriately while the pattern is protected.

It is preferred that the substrate treating apparatus described above further includes a gas supplying unit configured to supply dry gas to the upper surface of the substrate held with the substrate holder. This can dry the substrate effectively.

### BRIEF DESCRIPTION OF DRAWINGS

For the purpose of illustrating the invention, there are shown in the drawings several forms which are presently preferred, it being understood, however, that the invention is not limited to the precise arrangement and instrumentalities shown.

FIG. 1 is a plan view of an interior of a substrate treating apparatus according to a first embodiment.

FIG. 2 is a control block diagram of the substrate treating apparatus.

FIG. 3 shows the construction of a treating unit and a mixed liquid adjusting unit according to the first embodiment.

FIG. 4 is a flow chart showing procedures of a substrate treating method.

FIG. 5 schematically shows an upper surface of a substrate in a mixed liquid dispensing step.

FIG. 6 schematically shows the upper surface of the substrate in a solidified film forming step.

FIG. 7 schematically shows the upper surface of the substrate in the solidified film forming step.

FIG. 8 schematically shows the upper surface of the substrate in a sublimation step.

FIG. 9 schematically shows the upper surface of the substrate in the sublimation step.

FIG. 10 is a table showing evaluations of each substrate treated in a first experimental example and a first comparative example.

FIG. 11 is a table showing evaluations of each substrate treated in a second experimental example.

FIG. 12 is a graph showing a relationship between a concentration of water in the mixed liquid and a median value of collapse rates.

FIG. 13 exemplarily shows a mechanism for pattern collapse.

FIG. 14 exemplarily shows a mechanism for pattern collapse.

FIG. 15 exemplarily shows the mechanism for pattern collapse.

FIG. 16 exemplarily shows the mechanism for pattern collapse.

FIG. 17 exemplarily shows the mechanism for pattern collapse.

FIG. 18 shows the construction of a treating unit and a mixed liquid adjusting unit according to a second embodiment.

FIG. 19 shows the construction of a treating unit and a mixed liquid adjusting unit according to a third embodiment.

FIG. 20 shows the construction of a treating unit and a mixed liquid adjusting unit according to a fourth embodiment.

### DESCRIPTION OF EMBODIMENTS

The following describes a substrate treating method, a treating liquid, and a substrate treating apparatus of the present invention with reference to the drawings.

### 1. First Embodiment

### 1-1. Outline of Substrate Treating Apparatus

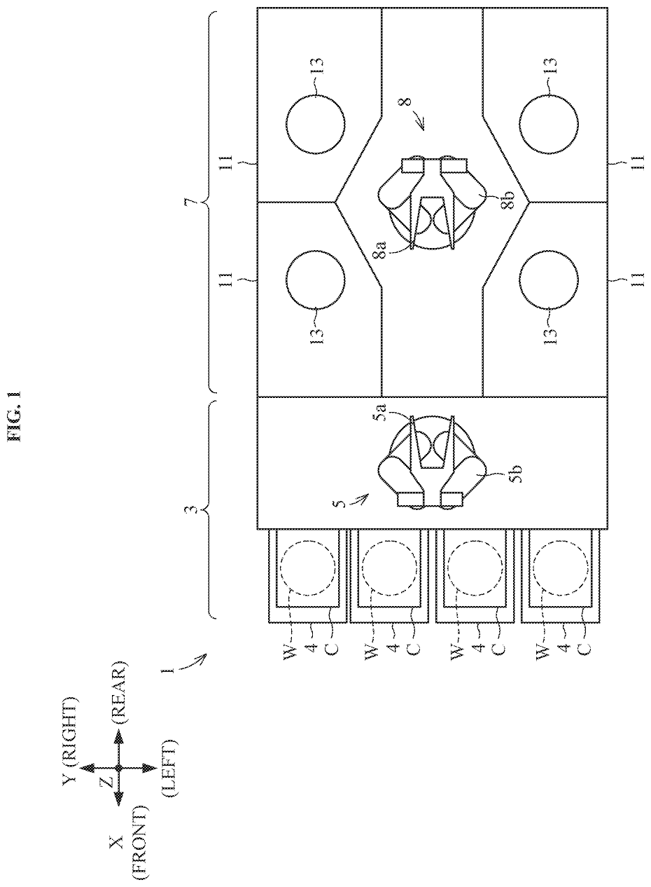

FIG. 1 is a plan view of an interior of a substrate treating apparatus according to the first embodiment. A substrate treating apparatus 1 performs treatment on a substrate W. The treatment performed on the substrate W includes a drying treatment.

Examples of the substrate W include a semiconductor wafer, a substrate for liquid crystal display, a substrate for organic electroluminescence (EL), a substrate for flat panel display (FPD), a substrate for optical display, a magnetic disk substrate, an optical disk substrate, a magneto-optical disk substrate, a substrate for photomask, and a solar cell substrate. The substrate W has a thin and flat plate shape. The substrate W has a substantially circular shape in plan view.

The substrate treating apparatus 1 includes an indexer 3, and a treating block 7. The treating block 7 is connected to the indexer 3. The indexer 3 supplies a substrate W to the treating block 7. The treating block 7 performs a treatment to the substrate W. The indexer 3 collects the substrate W from the treating block 7.

In this specification, the direction in which the indexer 3 and the treating block 7 are arranged is referred to as a “front-back direction X” for convenience. The front-back direction X is horizontal. One direction of the front-back direction X from the treating block 7 to the indexer 3 is referred to as a “forward direction”. The direction opposite to the forward direction is referred to as a “rearward direction”. A horizontal direction orthogonal to the front-back direction X is referred to as a “transverse direction Y”. Moreover, one direction of the transverse direction Y is referred to as a “rightward direction”, as appropriate. The direction opposite to the rightward direction is referred to as a “leftward direction”. The perpendicular direction relative to the horizontal direction is referred to as a “vertical direction Z”. For reference, the drawings show front, rear, right, left, up, and down, as appropriate.

The indexer 3 includes a plurality of (e.g., four) carrier platforms 4. The carrier platforms 4 each include one carrier C placed thereon. The carrier C accommodates a plurality of substrates W. The carrier C is, for example, a front opening unified pod (FOUP), a standard mechanical interface (SMIF), or an open cassette (OC).

The indexer 3 includes a transport mechanism 5. The transport mechanism 5 is arranged rearward of the carrier platforms 4. The transport mechanism 5 transports substrates W. The transport mechanism 5 is accessible to the carriers C placed on the carrier platforms 4, respectively. The transport mechanism 5 includes a hand 5a and a hand driving unit 5b. The hand 5a supports the substrate W. The hand driving unit 5b is coupled to the hand 5a. The hand driving unit 5b moves the hand 5a. The hand driving unit 5b moves the hand 5a in the front-back direction X, transverse direction Y, and vertical direction Z, for example. The hand driving unit 5b rotates the hand 5a in a horizontal plane, for example.

The treating block 7 includes a transport mechanism 8. The transport mechanism 8 transports substrates W. The transport mechanism 5 and the transport mechanism 8 are configured to transfer the substrate W to each other. The transport mechanism 8 includes a hand 8a and a hand driving unit 8b. The hand 8a supports the substrate W. The hand driving unit 8b is coupled to the hand 8a. The hand driving unit 8b moves the hand 8a. The hand driving unit 8b moves the hand 8a in the front-back direction X, transverse direction Y, and vertical direction Z, for example. The hand driving unit 8b rotates the hand 8a in a horizontal plane, for example.

The treating block 7 includes a plurality of treating units 11. The treating units 11 are each arranged laterally of the transport mechanism 8. The treating units 11 each perform a treatment on a substrate W individually.

The treating unit 11 includes a substrate holder 13. The substrate holder 13 holds the substrate W.

The transport mechanism 8 is accessible to the treating units 11 individually. The transport mechanism 8 can deliver the substrate W to the substrate holder 13. The transport mechanism 8 can take the substrate W from the substrate holder 13.

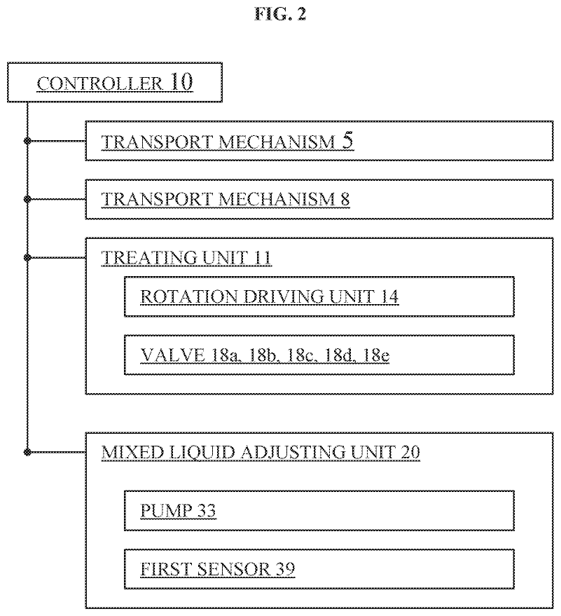

FIG. 2 is a control block diagram of the substrate treating apparatus 1. The substrate treating apparatus 1 includes a controller 10. The controller 10 controls the transport mechanisms 5, 8 and the treating units 11.

The controller 10 is implemented by a central processing unit (CPU) that performs various processes, a random-access memory (RAM) as a workspace of arithmetic processing, and a storage medium such as a fixed disk. The controller 10 contains various types of information stored in the storage medium in advance. The information stored in the controller 10 includes transportation information for controlling the transport mechanisms 5, 8, for example. The information stored in the controller 10 includes processing information for controlling the treating units 11, for example. The processing information is also called processing recipes.

The following simply describes one example of operation of the substrate treating apparatus 1.

The indexer 3 supplies substrates W to the treating block 7. Specifically, the transport mechanism 5 delivers the substrates W from the carrier C to the transport mechanism 8 of the treating block 7.

The treating block 7 distributes the substrates W from the indexer 3 to the treating unit 11. Specifically, the transport mechanism 8 transports the substrates W from the transport mechanism 5 to the substrate holders 13 of the treating units 11 individually.

The treating unit 11 performs treatment on the substrate W held by the substrate holder 13. The treating unit 11 performs a dry treatment, for example, on the substrate W.

After the treating unit 11 performs treatment on the substrate W, the treating block 7 returns the substrates W from the treating units 11 to the indexer 3. Specifically, the transport mechanism 8 transports the substrates W from the substrate holders 13 to the transport mechanism 5.

The indexer 3 collects the substrates W from the treating block 7. Specifically, the transport mechanism 5 transports the substrates W from the transport mechanism 8 to the carrier C.

### 1-2 Construction of Treating Unit 11

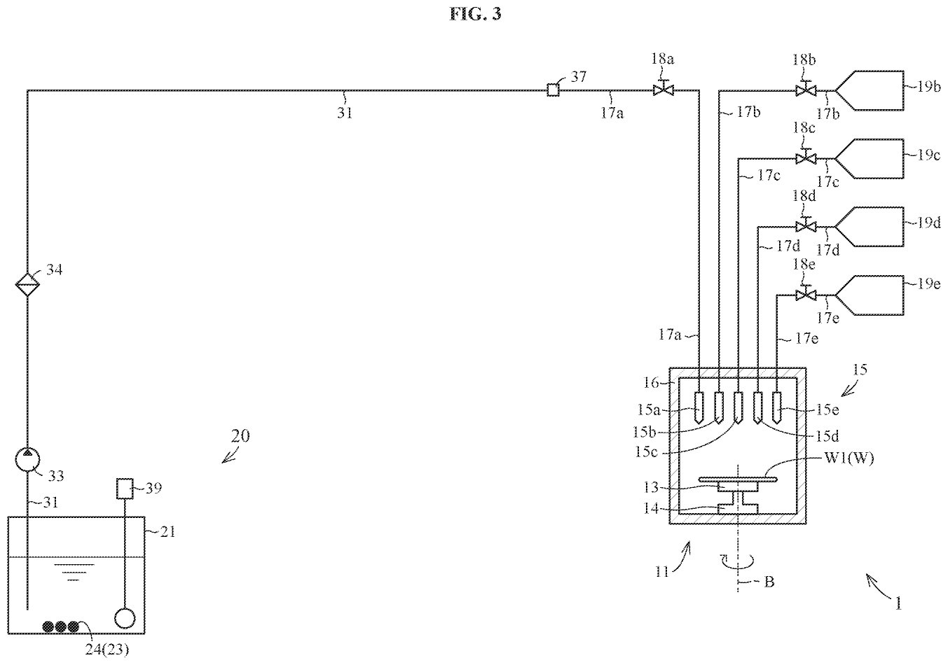

FIG. 3 shows the construction of the treating unit 11. The treating units 11 each have the same construction. The treating unit 11 is classified as a single-wafer processing unit. That is, the treating units 11 each perform a treatment on only one substrate W at one time.

The substrate holder 13 holds one substrate W. The substrate holder 13 holds the substrate W in a substantially horizontal posture. The substrate holder 13 holds a peripheral edge or a lower surface of the substrate W. The lower surface of the substrate W is also called a back side of the substrate W.

The treating units 11 each include a rotation driving unit 14. The rotation driving unit 14 is connected to the substrate holder 13. The rotation driving unit 14 rotates the substrate holder 13. The substrate W held by the substrate holder 13 rotates integrally with the substrate holder 13. The substrate W held by the substrate holder 13 rotates around a rotation axis B. The rotation axis B passes through the center of the substrate W and extends in the vertical direction Z, for example.

The treating unit 11 each includes a first nozzle 15a, a second nozzle 15b, a third nozzle 15c, a fourth nozzle 15d, and a fifth nozzle 15e. When no distinction is made between the first to fifth nozzles 15a to 15e hereunder, they are simply referred to as a “nozzle 15”. The nozzles 15 each dispense a liquid or gas to the substrate W. More specifically, the nozzles 15 each dispense a liquid or gas to an upper surface W1 of the substrate W held by the substrate holder 13. Each nozzle 15 is movable between a treating position and a standby position. The treating position is, for example, a position above the substrate W held by the substrate holder 13. The standby position is, for example, a position apart from the above of the substrate W held by the substrate holder 13.

The treating unit 11 includes a casing 16. The casing 16 has a substantial box shape. The casing 16 accommodates therein the substrate holder 13, the rotation driving unit 14, and the nozzles 15. The substrate W is treated within the casing 16.

The interior of the casing 16 is kept at normal temperatures. The interior of the casing 16 is kept at normal pressure. Accordingly, the substrate W is treated under an environment of normal temperatures and normal pressure. Here, the normal temperatures include a room temperature. The normal temperatures fall within a temperature range of 5 to 35 degrees centigrade, for example. The normal temperatures fall within a temperature range of 10 to 30 degrees centigrade, for example. The normal pressure includes standard atmospheric pressure (1 atm, 1,013 hPa). The normal pressure falls within a pressure range of 0.7 to 1.3 atm, for example. In the present specification, pressure is indicated as absolute pressure relative to absolute vacuum.

The treating unit 11 may further includes have a cup, not shown. The cup is located inside of the casing 16. The cup is arranged around the substrate holder 13. The cup receives the liquid scattered from the substrate W held by the substrate holder 13.

The treating unit 11 includes pipes 17a, 17b, 17c, 17d, and 17e. The pipes 17a, 17b, 17c, 17d, and 17e are connected to the first to fifth nozzles 15a to 15e, respectively. At least part of the pipe 17a may be provided externally of the casing 16. The same arrangement of the pipe 17a is applicable to arrangement of the pipes 17b to 17e.

The treating unit 11 includes vales 18a, 18b, 18c, 18d, and 18e. The valves 18a to 18e are provided on the pipes 17a to 17e, respectively. The valve 18a may be provided externally of the casing 16. The same arrangement of the valve 18a is applicable to arrangement of the valves 18b to 18e.

The substrate treating apparatus 1 includes a mixed liquid adjusting unit 20. The mixed liquid adjusting unit 20 is connected to the pipe 17a. The mixed liquid adjusting unit 20 is connected to the first nozzle 15a via the pipe 17a. The mixed liquid adjusting unit 20 is in fluid communication with the first nozzle 15a.

The mixed liquid adjusting unit 20 feeds a mixed liquid to the first nozzle 15a. The first nozzle 15a dispenses the mixed liquid. The mixed liquid adjusting unit 20 may feed the mixed liquid to a plurality of treating units 11.

The first nozzle 15a corresponds to one example of the dispensing unit in the present invention.

The pipe 17b is connected to a chemical liquid supplying source 19b. The chemical liquid supplying source 19b is connected in fluid communication with the second nozzle 15b. The chemical liquid supplying source 19b feeds a chemical liquid to the second nozzle 15b. The second nozzle 15b dispenses the chemical liquid.

The chemical liquid is, for example, an etchant. The chemical liquid includes, for example, at least either hydrofluoric acid (HF) or buffered hydrofluoric acid (BHF).

The pipe 17c is connected to a rinse liquid supplying source 19c. The rinse liquid supplying source 19c is connected in fluid communication with the third nozzle 15c. The rinse liquid supplying source 19c feeds a rinse liquid to the third nozzle 15c. The third nozzle 15c dispenses the rinse liquid.

The rinse liquid is, for example, deionized water (DIW).

The pipe 17d is connected to a replacement solution supplying source 19d. The replacement solution supplying source 19d is connected in fluid communication with the fourth nozzle 15d. The replacement solution supplying source 19d feeds a replacement solution to the fourth nozzle 15d. The fourth nozzle 15d dispenses the replacement solution.

The replacement solution is, for example, an organic solvent. The replacement solution is, for example, isopropyl alcohol (IPA).

The pipe 17e is connected to a dry gas supplying source 19e. The dry gas supplying source 19e is connected in fluid communication with the fifth nozzle 15e. The dry gas supplying source 19e feeds dry gas to the fifth nozzle 15e. The fifth nozzle 15e dispenses dry gas. The fifth nozzle 15e blows out dry gas.

The dry gas has a dew point lower than normal temperatures. The dew point is, for example, approximately -76 degrees centigrade. Accordingly, the dry gas does not dew at normal temperatures. A concentration of water in the dry gas is sufficiently low. The dry gas is, for example, air. The dry gas is, for example, compressed air. The dry gas is, for example, inert gas. The dry gas is, for example, nitrogen gas.

The fifth nozzle 15e corresponds to one example of the gas supplying unit in the present invention.

The chemical liquid supplying source 19b may be an element of the substrate treating apparatus 1. For example, the chemical liquid supplying source 19b may be a chemical tank included in the substrate treating apparatus 1. Alternatively, the chemical liquid supplying source 19b may not be an element of the substrate treating apparatus 1. For example, the chemical liquid supplying source 19b may be a utility equipment located externally of the substrate treating apparatus 1. Likewise, the rinse liquid supplying source 19c, the replacement solution supplying source 19d, and the dry gas supplying source 19e each may or may not be an element of the substrate treating apparatus 1.

Reference is made to FIG. 2. The controller 10 controls the rotation driving unit 14, and the valves 18a to 18e.

### 1-3. Construction of Mixed Liquid Adjusting Unit 20

Reference is made to FIG. 3. In the first embodiment, the mixed liquid adjusting unit 20 dehydrates the mixed liquid. Accordingly, the first nozzle 15a dispenses the dehydrated mixed liquid.

The mixed liquid adjusting unit 20 includes a first tank 21. The first tank 21 is in fluid communication with the first nozzle 15a. The first tank 21 is connected to the first nozzle 15a. The first tank 21 stores the mixed liquid.

The mixed liquid contains a sublimable substance and a solvent. The mixed liquid consists of only the sublimable substance and the solvent, for example.

Here, the “sublimable substance” corresponds to a substance having sublimability. “Sublimability” means a property that a single substance, a chemical compound or a mixture changes its phase from a solid phase to a gas phase or from a gas phase to a solid phase without passing through a liquid phase.

The sublimable substance preferably satisfies the following conditions 1-3 in addition to having sublimability.

Condition 1: The sublimable substance is solid at normal temperatures.

Condition 2: The sublimable substance is dissolvable in the solvent at normal temperatures.

Condition 3: The sublimable substance has vapor pressure of 0.01 Pa (absolute pressure) or more at normal temperatures.

The sublimable substance contains at least one selected from cyclohexanone oxime, camphor, naphthalene, and c-caprolactam, for example.

The solvent is a liquid at normal temperatures. The solvent dissolves the sublimable substance. The solvent preferably has vapor pressure at normal temperatures higher than the vapor pressure of the sublimable substance.

The solvent contains, for example, at least one selected from the following chemical compounds a1) to a10).

a1) acetone

a2) methanol

a3) ethanol

a4) isopropyl alcohol

a5) tert-butanol

a6) 1-propanol

a7) isobutanol

a8) 1-ethoxy-2-propanol

a9) 1-butanol

a10) propylene glycol monomethyl ether acetate

The sublimable substance in the mixed liquid is dissolved in the solvent. That is, the mixed liquid contains the solvent and the sublimable substance dissolved in the solvent.

Note that the replacement solution described above may be the same type liquid as the solvent. Moreover, the replacement solution described above may be a liquid similar to the solvent. At least one selected from the chemical compounds a1) to a10) may be contained in both the solvent and the replacement solution.

The mixed liquid adjusting unit 20 includes a dehydrating unit 23. The dehydrating unit 23 dehydrates the mixed liquid. The dehydrating unit 23 removes water, contained in the mixed liquid, from the mixed liquid.

The dehydrating unit 23 includes an absorber 24. The absorber 24 is installed in the first tank 21. The absorber 24 absorbs water contained in the mixed liquid. Water absorbed by the absorber 24 corresponds to water removed from the mixed liquid. In such a manner as above, the absorber 24 dehydrates the mixed liquid stored in the first tank 21.

Specifically, the absorber 24 is arranged in the mixed liquid stored in the first tank 21. The absorber 24 is immersed into the mixed liquid in the first tank 21. The absorber 24 contacts the mixed liquid. The absorber 24 selectively absorbs only water contained in the mixed liquid.

The absorber 24 has, for example, a granular shape, a cylindrical shape, a column shape, or a pellet shape. The absorber 24 has a porous shape, for example. The absorber 24 has hygroscopicity. The absorber 24 is zeolite, for example. The absorber 24 is a molecular sieve, for example. The absorber 24 is calcium oxide, for example. The absorber 24 is calcium sulfate, for example. The absorber 24 is also called a desiccating agent.

The mixed liquid adjusting unit 20 includes a pipe 31, a pump 33, a filter 34, and a joint 37. The pipe 31 is in fluid communication with the first tank 21. The pipe 31 is connected to the first tank 21. The pipe 31 extends from the first tank 21 to the pipe 17a. The pump 33 is provided on the pipe 31. The pump 33 feeds the mixed liquid from the first tank 21 to the pipe 31. The filter 34 is provided on the pipe 31. The filter 34 filters the mixed liquid flowing in the pipe 31. The filter 34 removes foreign substances from the mixed liquid. The foreign substances are, for example, the absorber 24. The joint 37 is connected to the pipe 31. The joint 37 is also connected to the pipe 17a. The pipe 31 is in fluid communication with the pipe 17a. The pipe 31 is in fluid communication with the first nozzle 15a. The first tank 21 is connected to the first nozzle 15a via the pipes 31 and 17a. Accordingly, the pump 33 feeds the mixed liquid from the first tank 21 to the pipe 17a (first nozzle 15a).

The mixed liquid adjusting unit 20 includes a first sensor 39. The first sensor 39 detects a concentration of water in the mixed liquid. The first sensor 39 detects the concentration of water in the mixed liquid with a Karl Fischer technique or an infrared absorption method, for example. The first sensor 39 is provided in the first tank 21, for example. The first sensor 39 detects the concentration of water in the mixed liquid stored in the first tank 21, for example.

Reference is made to FIG. 2. The controller 10 controls the mixed liquid adjusting unit 20. The controller 10 is communicably and electrically connected to the mixed liquid adjusting unit 20. The controller 10 obtains detection results of the first sensor 39. The controller 10 controls the pump 33.

The controller 10 contains adjustment information for controlling the mixed liquid adjusting unit 20. The adjustment information is stored in advance in the storage medium of the controller 10.

### 1-4. Operation Example of Mixed Liquid Adjusting Unit 20 and Treating Unit 11

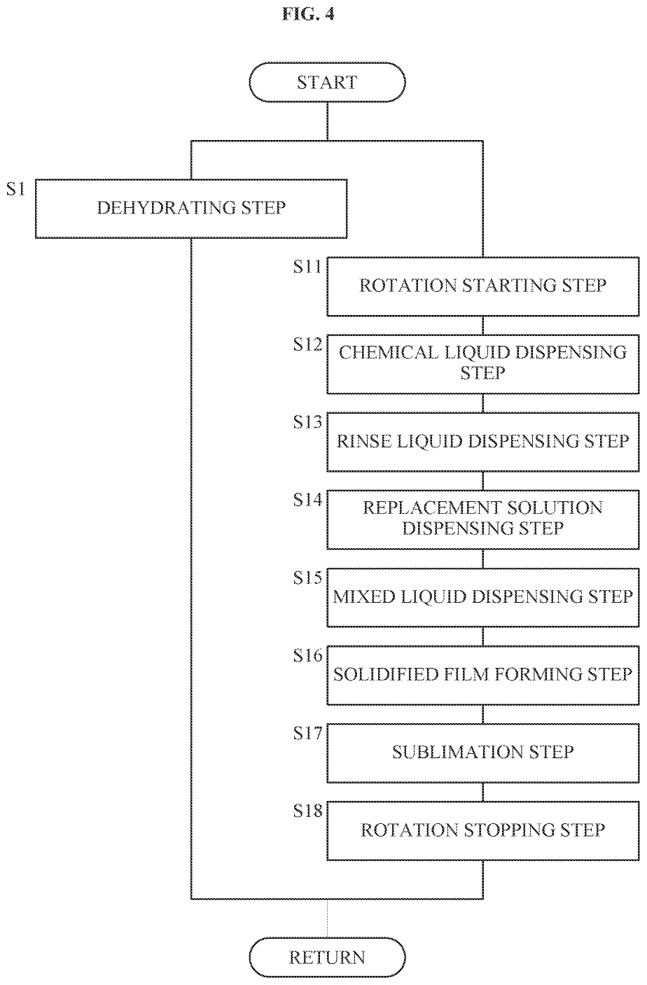

FIG. 4 is a flow chart showing procedures of a substrate treating method. The substrate treating method includes a Step S1 and Steps S11 to S18. The mixed liquid adjusting unit 20 performs the Step S1. The treating units 11 substantially perform the Steps S11 to S18. The Step S1 is executed in parallel with the Steps S11 to S18. The mixed liquid adjusting unit 20 and the treating units 11 operate in accordance with control by the controller 10.

Step S1: Dehydrating step

The dehydrating unit 23 dehydrates the mixed liquid. The dehydrating unit 23 dehydrates the mixed liquid in the first tank 21. The dehydrating unit 23 dehydrates the mixed liquid with use of the absorber 24. The absorber 24 dehydrates the mixed liquid stored in the first tank 21. In such a manner as above, the mixed liquid in the first tank 21 is dehydrated. The concentration of water in the mixed liquid in the first tank 21 becomes sufficiently low.

For example, it is preferred that a percent concentration of mass of water contained in the mixed liquid is made 2.5 wt % or less in the dehydrating step. It is more preferred that a percent concentration of mass of water contained in the mixed liquid is made 1.2 wt % or less in the dehydrating step. It is more preferred that a percent concentration of mass of water contained in the mixed liquid is made 0.7 wt % or less in the dehydrating step. It is more preferred that a percent concentration of mass of water contained in the mixed liquid is made 0.2 wt % or less in the dehydrating step. It is more preferred that a percent concentration of mass of water contained in the mixed liquid is made 0.1 wt % or less in the dehydrating step. It is more preferred that a percent concentration of mass of water contained in the mixed liquid is made 0.03 wt % or less in the dehydrating step.

The first sensor 39 detects the concentration of water in the mixed liquid. The controller 10 monitors detection results of the first sensor 39.

Step S11: Rotation starting step

The substrate holder 13 holds a substrate W. The rotation driving unit 14 rotates the substrate holder 13. The substrate W held by the substrate holder 13 starts rotation. The Steps S12 to S17 are executed while the substrate W rotates.

Step S12: Chemical liquid dispensing step

The valve 18b opens. The second nozzle 15b dispenses the chemical liquid onto the upper surface W1 of the substrate W held by the substrate holder 13. The chemical liquid is supplied onto the upper surface W1 of the substrate W. Then, the valve 18b closes. The second nozzle 15b stops dispensing the chemical liquid.

Step S13: Rinse liquid dispensing step

The valve 18c opens. The third nozzle 15c dispenses the rinse liquid onto the upper surface W1 of the substrate W held by the substrate holder 13. The rinse liquid is supplied onto the upper surface W1 of the substrate W. The rinse liquid cleans the substrate W. Specifically, the rinse liquid removes the chemical liquid from the upper surface W1 of the substrate W. Then, the valve 18c closes. The third nozzle 15c stops dispensing the rinse liquid.

Step S14: Replacement solution dispensing step

The valve 18d opens. The fourth nozzle 15d dispenses the replacement solution onto the upper surface W1 of the substrate W held by the substrate holder 13. The replacement solution is supplied onto the upper surface W1 of the substrate W. The replacement solution replaces the rinse liquid on the substrate W. In other words, the replacement solution removes the rinse liquid the substrate W. Then, the valve 18d closes. The fourth nozzle 15d stops dispensing the replacement solution.

Step S15: Mixed liquid dispensing step

The valve 18a opens. The first nozzle 15a dispenses the mixed liquid, dehydrated in the dehydrating step (Step S1), onto the upper surface W1 of the substrate W held by the substrate holder 13. The dehydrated mixed liquid is supplied onto the upper surface W1 of the substrate W. The dehydrated mixed liquid replaces the replacement solution on the substrate W. In other words, the dehydrated mixed liquid removes the replacement solution from the substrate W. Then, the valve 18a closes. The first nozzle 15a stops dispensing the dehydrated mixed liquid.

The mixed liquid adjusting unit 20 feeds the mixed liquid, dehydrated in the dehydrating step (Step S1), to the first nozzle 15a. Specifically, the pump 33 feeds the dehydrated mixed liquid from the first tank 21 to the pipe 17a.

FIG. 5 schematically shows the upper surface W1 of the substrate W in the mixed liquid dispensing step. The substrate W has a pattern P. The pattern P is formed on the upper surface W1 of the substrate W. In other words, when the substrate W is held by the substrate holder 13, the pattern P is positioned on the upper surface W1 of the substrate W. When the substrate W is held by the substrate holder 13, the pattern P is directed upward.

The pattern P may be formed before the treating unit 11 treats the substrate W, for example. The pattern P may be formed in the chemical liquid dispensing step (S12), for example.

The pattern P includes projections W2 and recesses A. The projections W2 are part of the substrate W. The projections W2 are a structure. The projections W2 are each formed with a silicon oxide (SiO₂) film, a silicon nitride (SiN) film, or a polysilicon film. The projections W2 project upward. The recess A is laterally adjacent to the projection W2. The recess A is a space. The recess A is open upward. The projection W2 corresponds to a wall defining the recess A.

A mixed liquid D is positioned on the upper surface W1 of the substrate W. The mixed liquid D forms a film that covers the upper surface W1 of the substrate W.

The mixed liquid D includes a top face D1. The top face D1 is positioned higher in level than the entire of the pattern P. The top face D1 is positioned higher in level than the entire of the projections W2. The pattern P is entirely immersed into the mixed liquid D. The projections W2 are entirely immersed into the mixed liquid D.

The recesses A are filled with the mixed liquid D. The recesses A are entirely filled only with the mixed liquid D.

Here, the replacement solution has already been removed from the upper surface W1 of the substrate W by the mixed liquid D. Consequently, there is no replacement solution on the upper surface W1 of the substrate W. No replacement solution remains in the recesses A.

Gas E exists above the mixed liquid D. The gas E contacts the top face D1. The top face D1 corresponds to a gas-liquid interface between the mixed liquid D and the gas E. The projections W2 do not contact the top face D1. Accordingly, the mixed liquid D forms no meniscus to the projections W2. Consequently, no surface tension of the mixed liquid D applies to the projections W2.

In the mixed liquid dispensing step, a height position of the top face D1 of the mixed liquid D may be adjusted additionally. The height position of the top face D1 corresponds to a film thickness of the mixed liquid D. For example, the height position of the top face D1 may be adjusted while the first nozzle 15a dispenses the mixed liquid D onto the substrate W. For example, the height position of the top face D1 may be adjusted after the first nozzle 15a stops dispensing the mixed liquid D. For example, the height position of the top face D1 may be adjusted by adjusting a rotation speed of the substrate W. For example, the height position of the top face D1 may be adjusted by adjusting a period of rotation of the substrate W.

The mixed liquid dispensing step as the Step S15 corresponds to one example of the dispensing step in the present invention.

Step S16: Solidified film forming step

The solvent evaporates from the mixed liquid D on the upper surface W1 of the substrate W. The solvent changes from liquid to gas. The solvent is removed from the upper surface W1 of the substrate W. Evaporation of the solvent causes the sublimable substance to be precipitated on the upper surface W1 of the substrate W. The solidified film is formed on the upper surface W1 of the substrate W. A solidified film contains the precipitated sublimable substance. The solidified film does not contain the solvent. The solidified film is solid.

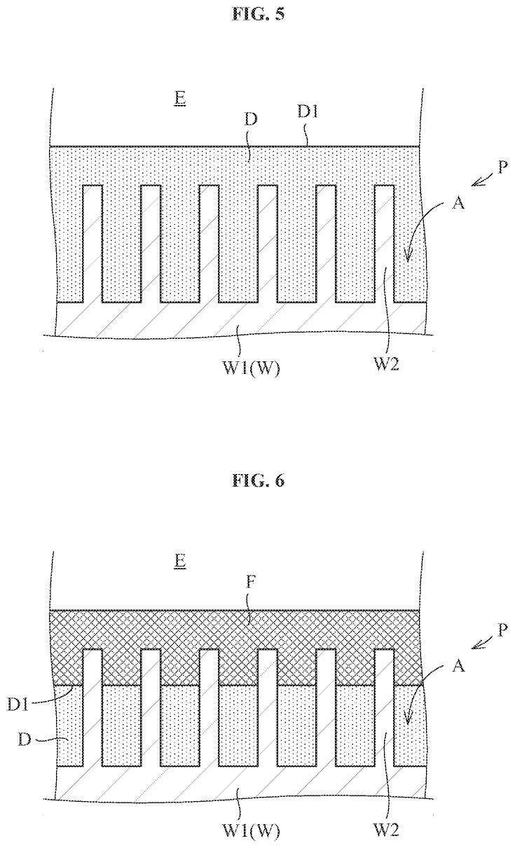

FIG. 6 schematically shows the upper surface W1 of the substrate W in the solidified film forming step. As the solvent evaporates from the mixed liquid D, the mixed liquid D gradually changes to the solidified film F. Firstly, a surface of the mixed liquid D changes to the solidified film F. That is, an upper part of the mixed liquid D changes to the solidified film F. The height position of the top face D1 of the mixed liquid D is lowered. The solidified film F covers the top face D1 of the mixed liquid D. The mixed liquid D remaining on the substrate W is positioned below the solidified film F.

The solidified film F contacts the gas E. The mixed liquid D does not contact the gas E. The top face D1 of the mixed liquid D does not contact the gas E. The top face D1 is covered with the solidified film F, whereby the gas-liquid interface between the mixed liquid D and the gas E disappears. Accordingly, the mixed liquid D decreases in the solidified film forming step without applying any significant force to the projections W2. The solvent is removed from the upper surface W1 of the substrate W without applying any significant force to the projections W2.

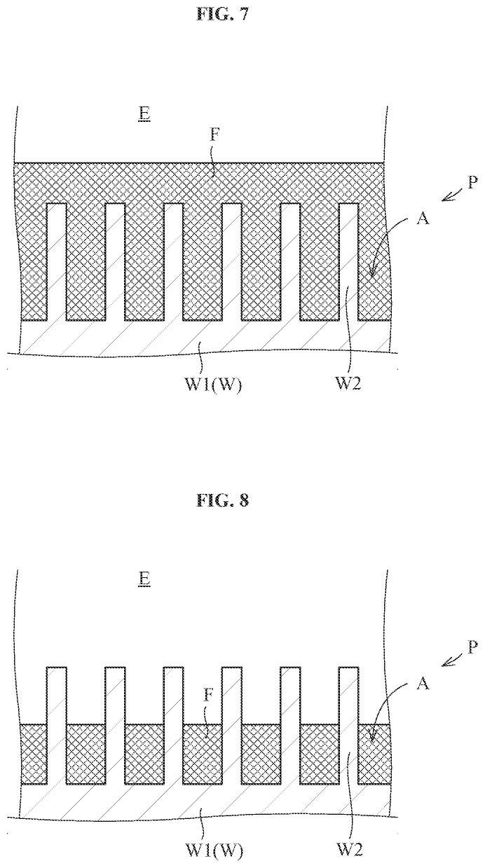

FIG. 7 schematically shows the upper surface W1 of the substrate W in the solidified film forming step. Finally, the mixed liquid D disappears from the upper surface W1 of the substrate W. This is because the solvent contained in the mixed liquid D is removed from the upper surface W1 of the substrate W and the sublimable substance contained in the mixed liquid D is changed into the solidified film. Accordingly, the mixed liquid D does not remain in the recesses A when the solidified film forming step completes. The recesses A are filled with the solidified film F. The recesses A are entirely filled only with the solidified film F. The pattern P contacts the solidified film F. The projections W2 contact the solidified film F.

There exists no liquid on the upper surface W1 of the substrate W. No liquid exists in the recesses A. The pattern P does not contact the liquid. The projections W2 do not contact the liquid.

Step S17: Sublimation step

The valve 18e opens. The fifth nozzle 15e supplies dry gas to the upper surface W1 of the substrate W held by the substrate holder 13. In other words, the fifth nozzle 15e supplies dry gas to the solidified film F on the substrate W. The solidified film F sublimates. The solidified film F changes from solid to gas without being a liquid. Such sublimation of the solidified film F causes the solidified film F to be removed from the upper surface W1 of the substrate W. Here, the sublimation step is also executed at normal temperatures. Accordingly, the dry gas does not condense into dew. Then, the valve 18e closes. The fifth nozzle 15e stops supplying the dry gas.

FIG. 8 schematically shows the upper surface W1 of the substrate W in the sublimation step. As the solidified film F sublimates, the solidified film F gradually decreases and gas E enters into the recesses A.

When the solidified film F sublimates, the solidified film F does not change to liquid. Accordingly, there exists no liquid on the upper surface W1 of the substrate W. No liquid exists in the recesses A. The pattern P does not contact the liquid. The projections W2 do not contact the liquid. The solidified film F is removed from the upper surface W1 of the substrate W without applying any significant force to the projections W2.

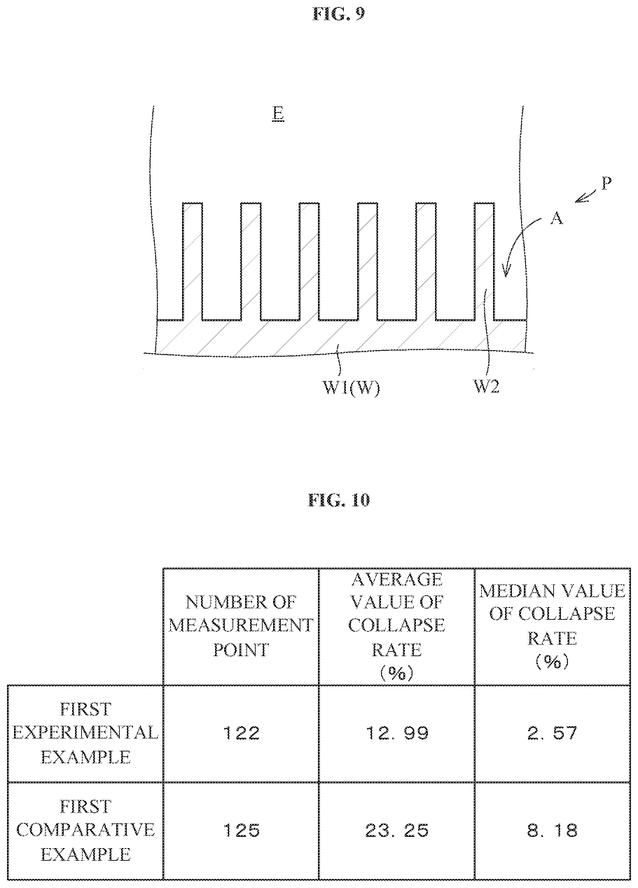

FIG. 9 schematically shows the upper surface W1 of the substrate W in the sublimation step. Finally, the solidified film F disappears from the upper surface W1 of the substrate W. The recesses A are filled with the gas E. The recesses A are entirely filled only with the gas E. There exists no liquid on the upper surface W1 of the substrate W. The substrate W is dried completely.

Step S18: Rotation stopping step

The rotation driving unit 14 stops rotating the substrate holder 13. The substrate W held by the substrate holder 13 stops rotation. The substrate W rests. The treating units 11 complete treatment on the substrate W.

### 1-5. Technical Meanings of Dehydrating Step

The following describes technical meanings of the dehydrating step from a first experimental example and a first comparative example.

The first experimental example is executed under conditions as below. That is, in the first experimental example, a series of treatment is performed on the substrate W, the series containing a chemical liquid dispensing step, a rinse liquid dispensing step, a replacement solution dispensing step, a mixed liquid dispensing step, a solidified film forming step, and a sublimation step. In the chemical liquid dispensing step, hydrofluoric acid is used as a chemical liquid. In the rinse liquid dispensing step, deionized water (DIW) is used as a rinse liquid. In the replacement solution dispensing step, isopropyl alcohol is used as a replacement solution.

The mixed liquid contains cyclohexanone oxime as a sublimable substance and isopropyl alcohol as solvent. The volume ratio of cyclohexanone oxime to isopropyl alcohol in the mixed liquid is as follows:

cyclohexanone oxime: isopropyl alcohol=1:40.

In the dehydrating step, the mixed liquid is dehydrated with use of the molecular sieve. Specifically, molecular sieve is added in the mixed liquid and the mixed liquid is allowed to stand for at least one day.

In the mixed liquid dispensing step, the mixed liquid dehydrated in the dehydrating step is used.

The first comparative example is executed under conditions as below. The dehydrating step is omitted. In the mixed liquid dispensing step, the mixed liquid not dehydrated is used. Specifically, in the mixed liquid dispensing step, the mixed liquid not dehydrated in the dehydrating step is used. Except for that, the first comparative example is executed under the same conditions as those in the first experimental example.

Substrates W treated in the first experimental example and the first comparative example are individually evaluated under the following evaluation criterions. An observer observes measurement points on a substrate W. Here, each measurement point is a minute region of any position on the substrate W. Each measurement point is magnified 50,000 times by a scanning electron microscopy. The observer counts the number N of projections W2 and the number n of collapsed projections W2 at each measurement point. Here, the number n is equal to or less than the number N. The observer calculates a collapse rate at each measurement point. In addition, the observer calculates an average value of the collapse rates and the median value of the collapse rates.

The collapse rate is defined by the numbers N and n as follows:

(a collapse rate at each measurement point)=n/N*100 (%)

The average value (%) of the collapse rates is obtained by dividing the sum of the collapse rates at each measurement point by the number of measurement points. The median value (%) of the collapse rates is the collapse rate located in the center of a sequence of the collapse rates at each measurement point arranged in degree of magnitudes.

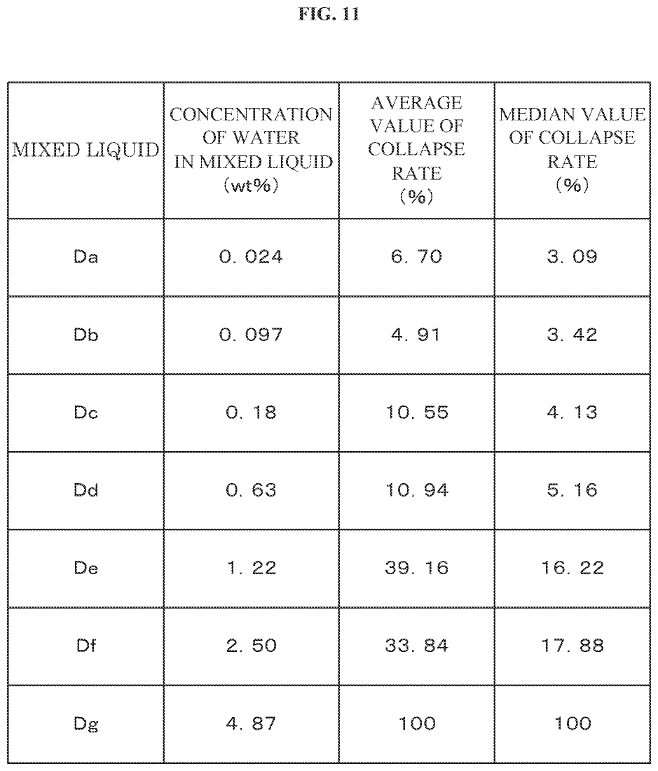

FIG. 10 is a table showing evaluations of each substrate W treated in the first experimental example and the first comparative example. In the first experimental example, the average value of the collapse rates was 12.99 (%). In the first experimental example, the median value of the collapse rates was 2.57 (%). In the first comparative example, the average value of the collapse rates was 23.25 (%). In the first comparative example, the median value of the collapse rates was 8.18 (%). The average value of the collapse rates in the first experimental example is significantly lower than that in the first comparative example. The median value of the collapse rates in the first experimental example is significantly lower than that in the first comparative example.

### 1-6. Relationship Between Water Concentration in Mixed Liquid and Collapse Rate of Pattern

The following describes a relationship between the concentration of water in the mixed liquid and the collapse rate of the pattern from a second experimental example.

In the second experimental example, a mixed liquid in which a concentration of water is intentionally changed is used in the mixed liquid dispensing step. Except for that, the second experimental example is executed under the same conditions as those in the first experimental example.

Specifically, seven types of mixed liquids Da, Db, Dc, Dd, De, Df and Dg are prepared. The mixed liquids Da, Db, Dc, Dd, De, Df and Dg have different concentrations of water in the mixed liquid. In the mixed liquid dispensing step, any one of the mixed liquids Da to Dg is used. Consequently, a series of treatment is executed at least seven times in the second experimental example. Then, seven types of substrates W are obtained. The seven types of substrates W are evaluated with the above evaluation criterions.

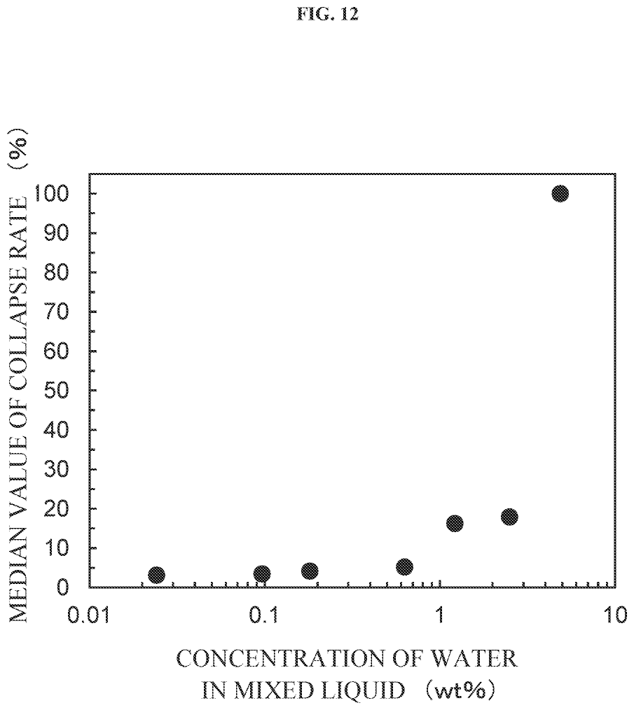

FIG. 11 is a table showing evaluations of each substrate W treated in the second experimental example. A term “water concentration in mixed liquid” in FIG. 11 corresponds to a percent concentration of mass of water contained in the mixed liquid. The concentration of water in the mixed liquid is determined with a Karl Fischer technique.

Basically, the average value of the collapse rates decreases as the concentration of water in the mixed liquid decreases. When the percent concentration of mass of water in the mixed liquid is 2.50 wt % or less, the average value of the collapse rates is less than 40%. When the percent concentration of mass of water in the mixed liquid is 1.22 wt % or less, the average value of the collapse rates is less than 40%. When the percent concentration of mass of water in the mixed liquid is 0.63 wt % or less, the average value of the collapse rates is less than 11%. When the percent concentration of mass of water in the mixed liquid is 0.18 wt % or less, the average value of the collapse rates is less than 11%. When the percent concentration of mass of water in the mixed liquid is 0.097 wt % or less, the average value of the collapse rates is less than 7%.

Reference is made to FIGS. 11 and 12. FIG. 12 is a graph showing a relationship between a concentration of water in the mixed liquid and a median value of collapse rates. The graph of FIG. 12 is a logarithmic graph (more specifically, semilogarithmic graph). The horizontal axis of the graph represents the concentration of water in the mixed liquid in logarithmic scale. The vertical axis of the graph represents the median value of collapse rates. Basically, the median value of the collapse rates decreases as the concentration of water in the mixed liquid decreases. When the concentration of water in the mixed liquid is 2.50 wt % or less, the median value of the collapse rates is less than 18%. When the concentration of water in the mixed liquid is 1.22 wt % or less, the median value of the collapse rates is less than 17%. When the concentration of water in the mixed liquid is 0.63 wt % or less, the median value of the collapse rates is less than 6%. When the concentration of water in the mixed liquid is 0.18 wt % or less, the median value of the collapse rates is less than 5%. When the concentration of water in the mixed liquid is 0.097 wt % or less, the median value of the collapse rates is less than 4%.

### 1-7. Mechanism of Prevention of Suitable Drying of Water in Mixed Liquid

As described above, the collapse rate of the pattern P increases as the concentration of water in the mixed liquid increases. The Inventors assume that such a phenomenon is caused by at least either a first reason or a second reason. In other words, the Inventors assume that at least either the first reason or the second reason is the reason for collapse of the pattern P.

The first reason is that the replacement solution remains in the recesses A when the mixed liquid dispensing step completes.

The second reason is that the mixed liquid remains in the recesses A when the solidified film forming step completes.

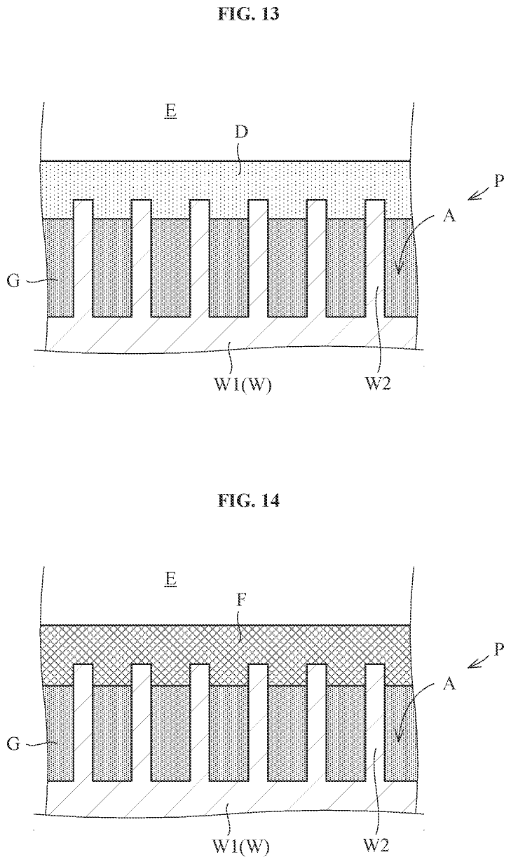

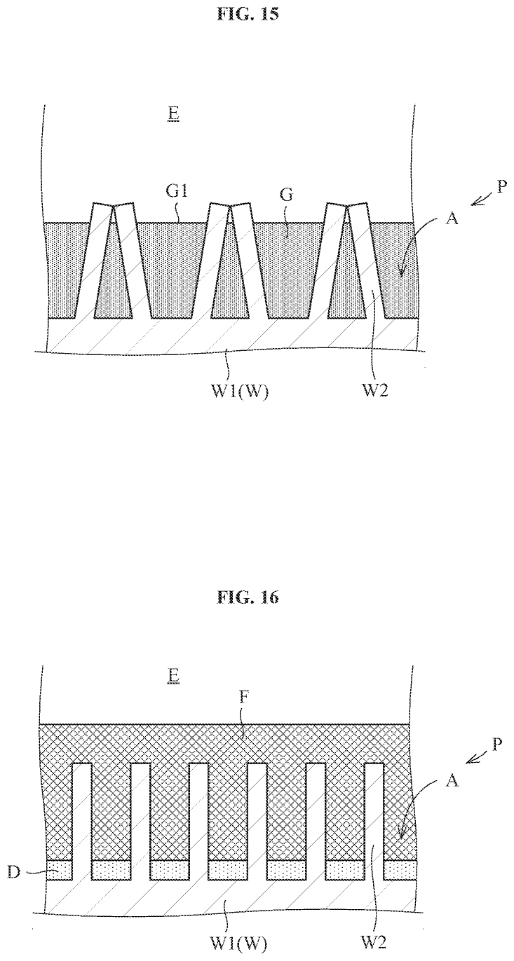

Now the first reason is to be described. FIGS. 13, 14, and 15 each exemplarily show a mechanism for collapse of pattern P. FIG. 13 schematically shows the upper surface W1 of the substrate W in the mixed liquid dispensing step. FIG. 14 schematically shows the upper surface W1 of the substrate W in the solidified film forming step. FIG. 15 schematically shows the upper surface W1 of the substrate W in the sublimation step. FIGS. 13 to 15 each show the case where the concentration of water in the mixed liquid D is high.

Reference is made to FIG. 13. The water is hydrophilic. The projections W2 have hydrophobicity. Accordingly, affinity between the mixed liquid D and the projections W2 decreases as the concentration of water in the mixed liquid D becomes higher. In other words, compatibility between the mixed liquid D and the projections W2 becomes worse as the concentration of water in the mixed liquid D increases. The recess A is adjacent to the projection W2. Consequently, the mixed liquid D hardly enters into the recesses A as the concentration of water in the mixed liquid D increases. Therefore, the mixed liquid D cannot remove the replacement solution G satisfactorily from the upper surface W1 of the substrate W in the mixed liquid dispensing step. When the mixed liquid dispensing step completes, the replacement solution G remains in the recesses A in the form of liquid. Even when the mixed liquid dispensing step completes, the recesses A are not entirely filled only with the mixed liquid D.

Reference is made to FIG. 14. As a result, in the solidified film forming step, the recesses A are not entirely filled only with the solidified film F. In other words, the solidified film F is not formed in the entire of the recesses A. Even when the solidified film forming step completes, the replacement solution G remains in the recesses A in the form of liquid.

Reference is made to FIG. 15. In the sublimation step, the solidified film F sublimates. The replacement solution G remains in the recesses A even after the solidified film F sublimates. The replacement solution G includes a top face G1. After the solidified film F sublimates, the top face G1 comes to contact gas E. The top face G1 corresponds to a gas-liquid interface between the replacement solution G and the gas E. The top face G1 contacts the projections W2. Accordingly, the replacement solution G forms meniscus to the projections W2. Consequently, a surface tension of the replacement solution G acts on the projections W2. The replacement solution G applies significant force to the projections W2. This results in collapse of the projections W2 (pattern P). For example, two adjacent projections W2 are attached to each other.

In contrast to this, the concentration of water in the mixed liquid D is made sufficiently low in the dehydrating step of the first embodiment. Then, affinity between the mixed liquid D and the projections W2 increases as the concentration of water in the mixed liquid D becomes lower. In other words, compatibility between the mixed liquid D and the projections W2 becomes better as the concentration of water in the mixed liquid D decreases. Consequently, the mixed liquid D easily enters into the recesses A as the concentration of water in the mixed liquid D decreases. Therefore, the mixed liquid D can remove the replacement solution satisfactorily from the upper surface W1 of the substrate Win the mixed liquid dispensing step. The mixed liquid D can suitably prevent the replacement solution from remaining in the recesses A (see FIG. 5). The replacement solution is removed from the upper surface W1 of the substrate W without applying any significant force to the projections W2. The projections W2 are suitably protected. Collapse of the pattern P can be suppressed suitably.

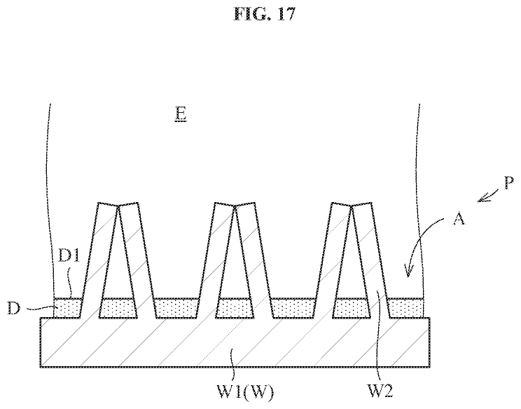

Now the second reason is to be described. FIGS. 16 and 17 each exemplarily show a mechanism for collapse of the pattern P. FIG. 16 schematically shows the upper surface W1 of the substrate W in the solidified film forming step. FIG. 17 schematically shows the upper surface W1 of the substrate Win the sublimation step. FIGS. 16 and 17 each show a case where the concentration of water in the mixed liquid D is high.

It is assumed that no replacement solution remains in the recesses A when the mixed liquid dispensing step completes. In this case, when the mixed liquid dispensing step completes, the recesses A are entirely filled only with the mixed liquid D (see FIG. 5).

Reference is made to FIG. 16. The solvent evaporates from the mixed liquid D in the solidified film forming step. However, water contained in the mixed liquid D hardly evaporates. This is because vapor pressure of water is lower than that of the solvent. If the concentration of water in the mixed liquid D is high, the mixed liquid D remains in the recesses A even after the solvent contained in the mixed liquid evaporates completely. As a result, the mixed liquid D remains in the recesses A when the solidified film forming step completes. The mixed liquid D remaining on the substrate W does not contain the solvent but contains water. Accordingly, the remaining mixed liquid D has a high concentration of water. The solidified film F is not formed in the entire of the recesses A.

Reference is made to FIG. 17. In the sublimation step, the solidified film F sublimates. The mixed liquid D remains in the recesses A even after the solidified film F sublimates. After the solidified film F sublimates, the top face D1 of the mixed liquid D comes to contact gas E. The top face D1 becomes a gas-liquid interface between the mixed liquid D and the gas E. The top face D1 contacts the projections W2. Accordingly, the mixed liquid D forms meniscus to the projections W2. Consequently, a surface tension of the mixed liquid D acts on the projections W2. Especially, the concentration of water in the mixed liquid D is high. Thus, the surface tension of the mixed liquid D is relatively high. Therefore, the mixed liquid D applies a significant force to the projections W2. This results in collapse of the projections W2 (pattern P).

In contrast to this, the concentration of water in the mixed liquid D is made sufficiently low in the dehydrating step of the first embodiment. When the concentration of water in the mixed liquid D is sufficiently low, the mixed liquid D disappears due to evaporation of the solvent and precipitation of the sublimable substance. That is, the mixed liquid D does not remain in the recesses A when the solidified film forming step completes (see FIG. 7). The mixed liquid D is removed from the upper surface W1 of the substrate W or changes into the solidified film E without applying any significant force to the projections W2. The mixed liquid D disappears from the upper surface W1 of the substrate W without applying any significant force to the projections W2. The projections W2 are suitably protected. Collapse of the pattern P can be suppressed suitably.

### 1-8. Effect of First Embodiment

The mixed liquid D contains the sublimable substance and the solvent. The substrate treating method includes the dehydrating step. In the dehydrating step, the mixed liquid D is dehydrated. In other words, water contained in the mixed liquid D is removed from the mixed liquid D in the dehydrating step. Through the dehydrating step, the concentration of water in the mixed liquid D is made sufficiently low. This can suitably prevent the mixed liquid D from taking water when the mixed liquid D is produced and used. This can suitably prevent increase in a concentration of water in the mixed liquid D when the mixed liquid D is produced and used.

The substrate treating method includes the mixed liquid dispensing step. In the mixed liquid dispensing step, the mixed liquid D dehydrated in the dehydrating step is dispensed onto the upper surface W1 of the substrate W. Accordingly, in the mixed liquid dispensing step where the mixed liquid D is dispensed onto the upper surface W1 of the substrate W, the concentration of water in the mixed liquid D is sufficiently low. Consequently, the mixed liquid D can be supplied onto the upper surface W1 of the substrate W appropriately in the mixed liquid dispensing step. For example, the mixed liquid D suitably removes the replacement solution from the upper surface W1 of the substrate W. For example, the replacement solution can be prevented from remaining in the recesses A in the form of liquid when the mixed liquid dispensing step completes. For example, the recesses A can be entirely filled only with the mixed liquid D when the mixed liquid dispensing step completes.

The substrate treating method includes the solidified film forming step. In the solidified film forming step, the solvent evaporates from the mixed liquid D on the upper surface W1 of the substrate W. In the solidified film forming step, the solidified film F is formed on the upper surface W1 of the substrate W. The solidified film F contains the sublimable substance. As described above, in the mixed liquid dispensing step where the mixed liquid D is dispensed onto the upper surface W1 of the substrate W, the concentration of water in the mixed liquid D is sufficiently low. Consequently, in the solidified film forming step, the solidified film F can be formed on the upper surface W1 of the substrate W appropriately. For example, the mixed liquid D appropriately disappears from the upper surface W1 of the substrate W. For example, the mixed liquid D can be prevented from remaining in the recesses A when the solidified film forming step completes. For example, water can be prevented from remaining in the recesses A when the solidified film forming step completes. For example, the solidified film F can be formed entirely in the recesses A in the solidified film forming step. For example, the recesses A can entirely be filled only with the solidified film F in the solidified film forming step.

The substrate treating method includes the sublimation step. In the sublimation step, the solidified film F sublimates. In other words, the solidified film F changes to gas without being a liquid in the sublimation step. By sublimation of the solidified film F, the solidified film F is removed from the upper surface W1 of the substrate W. As described above, in the mixed liquid dispensing step where the mixed liquid D is dispensed onto the upper surface W1 of the substrate W, the concentration of water in the mixed liquid D is sufficiently low. Consequently, in the sublimation step, the substrate W can be dried appropriately. For example, the solidified film F can be removed from the upper surface W1 of the substrate W without forming the gas-liquid interface in contact with the projections W2 in the sublimation step.

In summary, the substrate treating method described above achieves proper drying of substrates W.

In the dehydrating step, a mass percent concentration of water contained in the mixed liquid D is made 1.2 wt % or less, for example. Accordingly, in the mixed liquid dispensing step where the mixed liquid D is dispensed onto the upper surface W1 of the substrate W, the concentration of water in the mixed liquid D is sufficiently low. Consequently, the mixed liquid D can be supplied onto the upper surface W1 of the substrate W suitably in the mixed liquid dispensing step. In the solidified film forming step, the solidified film F can be formed on the upper surface W1 of the substrate W more appropriately. In the sublimation step, the substrate W can be dried more appropriately.

In the dehydrating step, the mixed liquid D is dehydrated with use of the absorber 24. The absorber 24 absorbs water in the mixed liquid D. Accordingly, in the dehydrating step, the mixed liquid D can be dehydrated suitably.

In the mixed liquid dispensing step, the first nozzle 15a dispenses the mixed liquid D onto the upper surface W1 of the substrate W. The dehydrating step is executed in the tank (specifically, first tank 21) that is in fluid communication with the first nozzle 15a. Specifically, the mixed liquid D, stored in the first tank 21 that is in fluid communication with the first nozzle 15a, is dehydrated in the dehydrating step. Accordingly, in the mixed liquid dispensing step where the mixed liquid D is dispensed onto the upper surface W1 of the substrate W, the concentration of water in the mixed liquid D is sufficiently low.

The absorber 24 is installed in the first tank 21. Accordingly, the dehydrating step is executed suitably in the first tank 21 that is in fluid communication with the first nozzle 15a.

The solvent includes at least one selected from the above chemical compounds a1) to a10) described above. Consequently, the substrate W can be dried appropriately.

The sublimable substance contains at least one selected from cyclohexanone oxime, camphor, naphthalene, and c-caprolactam. Consequently, the substrate W can be dried appropriately.

In the sublimation step, dry gas E is supplied to the solidified film F. Accordingly, the solidified film F can sublimate effectively in the sublimation step.

The substrate W has the pattern P formed on the upper surface W1 of the substrate W. With the substrate treating method, the substrate W can be dried appropriately while the pattern P is protected. With the substrate treating method, the substrate W can be dried appropriately while collapse of the pattern P is suppressed.

A treatment liquid used in the mixed liquid dispensing step is the dehydrated mixed liquid. Specifically, the treatment liquid used in the mixed liquid dispensing step is a treatment liquid obtained by dehydrating the mixed liquid containing the sublimable substance and the solvent. Accordingly, the treatment liquid used in the mixed liquid dispensing step has a sufficiently low concentration of water. The treatment liquid used in the mixed liquid dispensing step is a treatment liquid for drying substrates W. Specifically, the treatment liquid used in the mixed liquid dispensing step is a treatment liquid for sublimation drying substrates W. Accordingly, the substrate W can be suitably dried.

The substrate treating apparatus 1 includes the substrate holder 13, the dehydrating unit 23, and the first nozzle 15a. The substrate holder 13 holds the substrate W in a substantially horizontal posture. The dehydrating unit 23 dehydrates the mixed liquid D containing the sublimable substance and the solvent. The first nozzle 15a dispenses the mixed liquid D, dehydrated by the dehydrating unit 23, onto the upper surface W1 of the substrate W held by the substrate holder 13. Accordingly, when the first nozzle 15a dispenses the mixed liquid D onto the upper surface W1 of the substrate W held by the substrate holder 13, a concentration of water in the mixed liquid D is sufficiently low. Consequently, the substrate treating apparatus 1 can perform the substrate treating method of the first embodiment appropriately. That is, the substrate treating apparatus 1 can dry substrates W appropriately.

The dehydrating unit 23 includes the absorber 24. The absorber 24 absorbs water in the mixed liquid D. Accordingly, dehydrating unit 23 can dehydrate the mixed liquid D suitably.

When the substrate W is held by the substrate holder 13, the substrate W has the pattern P formed on the upper surface W1 of the substrate W. Accordingly, the substrate treating apparatus 1 can dry the substrate W appropriately while the pattern P is protected.

The substrate treating apparatus 1 includes the fifth dispensing nozzle 15e. The fifth dispensing nozzle 15e supplies dry gas E to the upper surface W1 of the substrate W held with the substrate holder 13. This can dry the substrate W effectively.

The substrate treating apparatus 1 includes the first sensor 39 and the controller 10. The first sensor 39 measures a concentration of water in the mixed liquid D. The controller 10 obtains detection results of the first sensor 39. Accordingly, the controller 10 can monitor the concentration of water in the mixed liquid D suitably.

### 2. Second Embodiment

The following describes a substrate treating apparatus 1 according to a second embodiment with reference to drawings. Like numerals are used to identify like components which are the same as those in the first embodiment, and the components will not particularly be described.

The second embodiment has an outline of a substrate treating apparatus 1 and a construction of treating units 11 substantially same as those in the first embodiment. The following describes a construction of a mixed liquid adjusting unit 20 according to the second embodiment.

### 2-1. Construction of Mixed Liquid Adjusting Unit 20

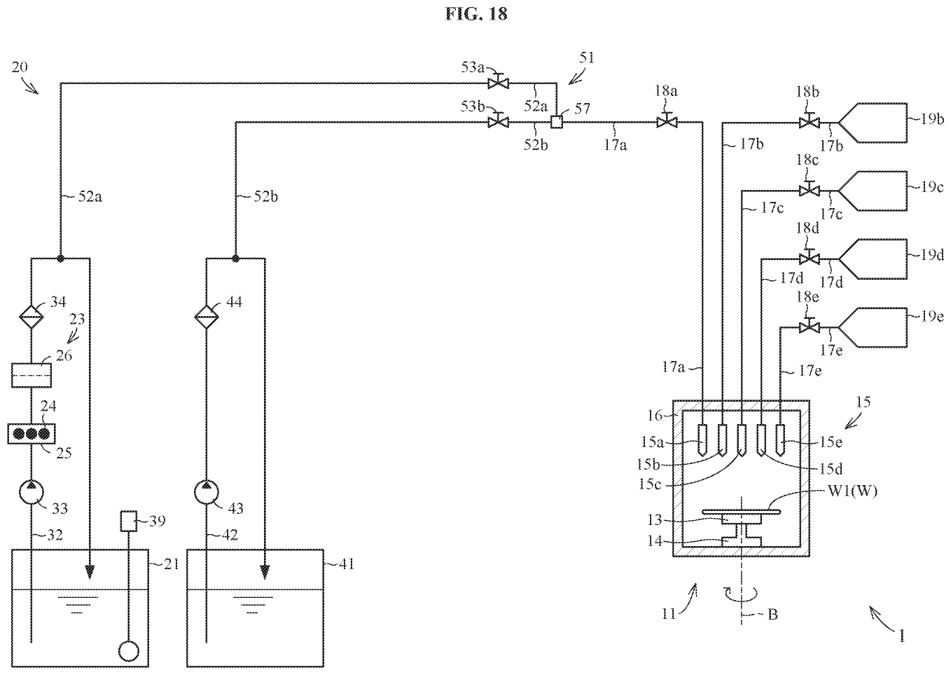

FIG. 18 shows the construction of a treating unit 11 and a mixed liquid adjusting unit 20 according to the second embodiment. In the second embodiment, the mixed liquid adjusting unit 20 dehydrates a first treatment liquid. Accordingly, a first nozzle 15a dispenses the dehydrated first treatment liquid. More specifically, the first nozzle 15a dispenses a mixed liquid obtained by adding a sublimable substance to the dehydrated first treatment liquid.

A first tank 21 stores the first treatment liquid. In the second embodiment, the first tank 21 does not store the mixed liquid.

The first treatment liquid contains the solvent. The solvent contained in the first treatment liquid includes at least one selected from the chemical compounds a1) to a10) described above, for example.

The first treatment liquid does not contain any sublimable substance, for example. The first treatment liquid consists of only a solvent, for example.

The first sensor 39 detects a concentration of water in the first treatment liquid.

The mixed liquid adjusting unit 20 includes a circulation pipe 32. The circulation pipe 32 is provided externally of the first tank 21. The circulation pipe 32 includes a first end communicating with the first tank 21, and a second end communicating with the first tank 21. The first end of the circulation pipe 32 is connected to the first tank 21. The second end of the circulation pipe 32 is connected to the first tank 21.

A pump 33 and a filter 34 are each provided on the circulation pipe 32. When the pump 33 actuates, the first treatment liquid circulates in the first tank 21 and the circulation pipe 32. Specifically, the first treatment liquid flows out from the first tank 21 to the circulation pipe 32 through the first end of the circulation pipe 32, and returns back to the first tank 21 from the circulation pipe 32 through the second end of the circulation pipe 32.

The dehydrating unit 23 is provided in the circulation pipe 32. The dehydrating unit 23 dehydrates the first treatment liquid flowing in the circulation pipe 32. The first treatment liquid dehydrated by the dehydrating unit 23 returns back to the first tank 21.

The dehydrating unit 23 includes a housing 25 in addition to an absorber 24. The housing 25 is in fluid communication with the circulation pipe 32. The housing 25 is connected to the circulation pipe 32. The housing 25 accommodates the absorber 24. The absorber 24 is provided in the circulation pipe 32 by means of the housing 25. The absorber 24 contacts the first treatment liquid flowing in the circulation pipe 32. The absorber 24 absorbs water contained in the first treatment liquid. This causes the absorber 24 to dehydrate the first treatment liquid flowing in the circulation pipe 32.

The dehydrating unit 23 includes a separator 26. The separator 26 is provided in the circulation pipe 32. The separator 26 removes water, contained in the first treatment liquid, from the first treatment liquid. This causes the separator 26 to dehydrate the first treatment liquid flowing in the circulation pipe 32. Here, the separator 26 is connected in fluid communication with a drain tube, not shown. The separator 26 discharges water, separated from the first treatment liquid, to the drain tube.

The separator 26 is a dehydrate filter, for example. The separator 26 includes a separation membrane, for example. The separator 26 includes a zeolite membrane, for example.

The mixed liquid adjusting unit 20 includes a second tank 41 in addition to the first tank 21. The second tank 41 is in fluid communication with the first nozzle 15a. The second tank 41 is connected to the first nozzle 15a. The second tank 41 stores a second treatment liquid.

The second treatment liquid contains a sublimable substance. The sublimable substance contains at least one selected from cyclohexanone oxime, camphor, naphthalene, and c-caprolactam, for example.

The second treatment liquid contains a solvent, for example. The solvent contained in the second treatment liquid is of the same type as the solvent contained in the first treatment liquid, for example. The solvent contained in the second treatment liquid has, for example, a composition equal to a composition of the solvent contained in the first treatment liquid.

The mixed liquid adjusting unit 20 includes a circulation pipe 42, a pump 43, and a filter 44. The circulation pipe 42 is provided externally of the second tank 41. The circulation pipe 42 includes a first end communicating with the second tank 41, and a second end communicating with the second tank 41. The first end of the circulation pipe 42 is connected to the second tank 41. The second end of the circulation pipe 42 is connected to the second tank 41. The pump 43 is provided in the circulation pipe 42. The pump 43 feeds the second treatment liquid. When the pump 43 actuates, the second treatment liquid circulates in the second tank 41 and the circulation pipe 42. Specifically, the second treatment liquid flows out from the second tank 41 to the circulation pipe 42 through the first end of the circulation pipe 42, and returns back to the second tank 41 from the circulation pipe 42 through the second end of the circulation pipe 42. The filter 44 is provided in the circulation pipe 42. The filter 44 filters the second treatment liquid flowing in the circulation pipe 42. The filter 44 removes foreign substances from the second treatment liquid.

The mixed liquid adjusting unit 20 includes a mixing unit 51. The mixing unit 51 produces a mixed liquid by adding the dehydrated first treatment liquid to the second treatment liquid.

The mixing unit 51 includes pipes 52a and 52b. The pipe 52a branches from the circulation pipe 32. The pipe 52a is connected to the circulation pipe 32. The pipe 52a is in fluid communication with the circulation pipe 32. The pipe 52b branches from the circulation pipe 42. The pipe 52b is connected to the circulation pipe 42. The pipe 52b is in fluid communication with the circulation pipe 42.

The mixing unit 51 includes valves 53a and 53b. The valve 53a is provided on the pipe 52a. The valve 53b is provided on the pipe 52b.

The mixing unit 51 includes a joint 57. The joint 57 connects the pipe 52a and pipe 52b. The joint 57 is also connected to the pipe 17a. The pipes 52a and 52b and the pipe 17a are in fluid communication with one another through the joint 57.

The circulation pipe 32 is in fluid communication with the first nozzle 15a. The circulation pipe 32 is connected to the first nozzle 15a via the pipes 52a and 17a. The first tank 21 is connected to the first nozzle 15a via the circulation pipe 32 and the pipes 52a and 17a.

The circulation pipe 42 is in fluid communication with the first nozzle 15a. The circulation pipe 42 is connected to the first nozzle 15a via the pipes 52b and 17a. The second tank 41 is connected to the first nozzle 15a via the circulation pipe 42 and the pipes 52b and 17a.

The controller 10 controls the pump 43 and the valves 53a and 53b, which illustration is omitted.

### 2-2. Operation Example of Mixed Liquid Adjusting Unit 20 and Treating Unit 11

Reference is made to FIG. 4. Similarly to the first embodiment, the substrate treating method according to the second embodiment includes a Step S1 and Steps S11 to S18. Operation in the Steps S11 to S14 and S16 to S18 are substantially common between the first embodiment and the second embodiment. Accordingly, description about the operation in the Steps S11 to S14 and S16 to S18 is to be omitted. The following describes operation in Steps 51 and S15.

Step S1: Dehydrating step

The dehydrating unit 23 dehydrates the first treatment liquid. The dehydrating unit 23 dehydrates the first treatment liquid in the circulation pipe 32. The dehydrating unit 23 dehydrates the first treatment liquid with use of the absorber 24 and the separator 26. Specifically, the pump 33 operates. The first treatment liquid circulates between the first tank 21 and the circulation pipe 32. The absorber 24 dehydrates the first treatment liquid flowing in the circulation pipe 32. The separator 26 also dehydrates the first treatment liquid flowing in the circulation pipe 32. Accordingly, the first treatment liquid flowing in the circulation pipe 32 is dehydrated. The dehydrated first treatment liquid returns back to the first tank 21. A concentration of water in the first treatment liquid in the first tank 21 becomes sufficiently low.

For example, it is preferred that a percent concentration of mass of water contained in the first treatment liquid is made 2.5 wt % or less in the dehydrating step. It is more preferred that a percent concentration of mass of water contained in the first treatment liquid is 1.2 wt % or less in the dehydrating step. It is more preferred that a percent concentration of mass of water contained in the first treatment liquid is 0.7 wt % or less in the dehydrating step. It is more preferred that a percent concentration of mass of water contained in the first treatment liquid is 0.2 wt % or less in the dehydrating step. It is more preferred that a percent concentration of mass of water contained in the first treatment liquid is 0.1 wt % or less in the dehydrating step. It is more preferred that a percent concentration of mass of water contained in the first treatment liquid is 0.03 wt % or less in the dehydrating step.

The first sensor 39 detects a concentration of water in the first treatment liquid. The controller 10 monitors detection results of the first sensor 39.

Step S15: Mixed liquid dispensing step

The pumps 33 and 43 operate. The valves 53a and 53b open. Moreover, the valve 18a opens. The dehydrated first treatment liquid flows from the circulation pipe 32 to the pipe 52a. The second treatment liquid flows from the circulation pipe 42 to the pipe 52b. The first treatment liquid and the second treatment liquid merge at the joint 57. The second treatment liquid is added to the dehydrated first treatment liquid. That is, the sublimable substance is added to the dehydrated first treatment liquid. The mixed liquid obtained by adding the sublimable substance to the dehydrated first treatment liquid flows to the first nozzle 15a through the pipe 17a. The first nozzle 15a dispenses the mixed liquid, obtained by adding the sublimable substance to the dehydrated first treatment liquid, onto the upper surface W1 of the substrate W held by the substrate holder 13. The mixed liquid is supplied onto the upper surface W1 of the substrate W. The mixed liquid replaces the replacement solution on the substrate W. Then, the valves 18a, 53a, and 53b close. The first nozzle 15a stops dispensing the mixed liquid.

### 2-3. Effect of Second Embodiment>

The second embodiment produces a similar effect to that of the first embodiment.

The substrate treating method includes the dehydrating step and the mixed liquid dispensing step. In the dehydrating step, the first treatment liquid is dehydrated. In other words, water contained in the first treatment liquid is removed from the first treatment liquid in the dehydrating step. The first treatment liquid contains the solvent. Through the dehydrating step, a concentration of water in the first treatment liquid is made sufficiently low. In the mixed liquid dispensing step, the mixed liquid is dispensed onto the upper surface W1 of the substrate W. The mixed liquid is obtained by adding the sublimable substance to the first treatment liquid, dehydrated in the dehydrating step. The mixed liquid contains the first treatment liquid dehydrated in the dehydrating step. The mixed liquid further contains the sublimable substance. This can suitably prevent the mixed liquid from taking water when the mixed liquid is produced and used. This can suitably prevent increase in the concentration of water in the mixed liquid when the mixed liquid is produced and used. Accordingly, in the mixed liquid dispensing step where the mixed liquid is dispensed onto the upper surface W1 of the substrate W, the concentration of water in the mixed liquid is sufficiently low. Consequently, the mixed liquid can be supplied onto the upper surface W1 of the substrate W appropriately in the mixed liquid dispensing step. For example, the mixed liquid suitably removes the replacement solution from the substrate W. For example, the replacement solution can be prevented from remaining in recesses A in the form of liquid when the mixed liquid dispensing step completes. For example, the recesses A can be entirely filled only with the mixed liquid when the mixed liquid dispensing step completes.

The substrate treating method includes a solidified film forming step. In the solidified film forming step, the solvent evaporates from the mixed liquid on the upper surface W1 of the substrate W. In the solidified film forming step, the solidified film is formed on the upper surface W1 of the substrate W. The solidified film contains the sublimable substance. As described above, in the mixed liquid dispensing step where the mixed liquid is dispensed onto the upper surface W1 of the substrate W, the concentration of water in the mixed liquid is sufficiently low. Consequently, in the solidified film forming step, the solidified film can be formed on the upper surface W1 of the substrate W appropriately. For example, the mixed liquid appropriately disappears from the upper surface W1 of the substrate W. For example, the mixed liquid can be prevented from remaining in the recesses A when the solidified film forming step completes. For example, water can be prevented from remaining in the recesses A when the solidified film forming step completes. For example, the solidified film can be formed entirely in the recesses A in the solidified film forming step. For example, the recesses A can entirely be filled only with the solidified film in the solidified film forming step.

The substrate treating method includes a sublimation step. In the sublimation step, the solidified film sublimates. In other words, the solidified film changes into gas without being a liquid in the sublimation step. By sublimation of the solidified film, the solidified film is removed from the upper surface W1 of the substrate W. As described above, in the mixed liquid dispensing step where the mixed liquid is dispensed onto the upper surface W1 of the substrate W, the concentration of water in the mixed liquid is sufficiently low. Consequently, in the sublimation step, the substrate can be dried appropriately. For example, the solidified film can be removed from the upper surface W1 of the substrate W without forming the gas-liquid interface in contact with the projections W2 in the sublimation step.

In summary, the substrate treating method described above achieves proper drying of substrates W.

In the dehydrating step, a mass percent concentration of water contained in the first treatment liquid is made 1.2 wt % or less, for example. Consequently, the mixed liquid can be supplied onto the upper surface W1 of the substrate W suitably in the mixed liquid dispensing step. In the solidified film forming step, the solidified film can be formed on the upper surface W1 of the substrate W more appropriately. In the sublimation step, the substrate W can be dried more appropriately.

In the dehydrating step, the mixed liquid is dehydrated with use of the absorber 24 and the separator 26. The absorber 24 absorbs water in the first treatment liquid. The separator 26 separates water from the first treatment liquid. Accordingly, in the dehydrating step, the first treatment liquid can be dehydrated suitably.

The dehydrating step is executed in the flow path (specifically, circulation pipe 32) that is in fluid communication with the first nozzle 15a. Specifically, the first treatment liquid, flowing in the circulation pipe 32 that is in fluid communication with the first nozzle 15a, is dehydrated in the dehydrating step. Accordingly, in the mixed liquid dispensing step where the mixed liquid is dispensed onto the upper surface W1 of the substrate W, the concentration of water in the mixed liquid is sufficiently low.

The absorber 24 and the separator 26 are installed in the circulation pipe 32. Accordingly, the dehydrating step is executed suitably in the circulation pipe 32 that is in fluid communication with the first nozzle 15a.

The mixed liquid is obtained by adding the second treatment liquid containing the sublimable substance to the first treatment liquid. That is, the sublimable substance is added to the first treatment liquid in a state where the sublimable substance is dissolved in the second treatment liquid. This can suitably obtain the mixed liquid containing the sublimable substance and the solvent.

A treatment liquid used in the mixed liquid dispensing step contains the dehydrated first treatment liquid. Specifically, the treatment liquid used in the mixed liquid dispensing step is a treatment liquid obtained by dehydrating the first treatment liquid containing the solvent and adding the sublimable substance to the dehydrated first treatment liquid. Accordingly, the treatment liquid used in the mixed liquid dispensing step has a sufficiently low concentration of water. The treatment liquid used in the mixed liquid dispensing step is a treatment liquid for drying substrates W. Specifically, the treatment liquid used in the mixed liquid dispensing step is a treatment liquid for sublimation drying substrates W. Accordingly, the substrate W can be suitably dried.

The substrate treating apparatus 1 includes the substrate holder 13, the dehydrating unit 23, and the first nozzle 15a. The dehydrating unit 23 dehydrates the first treatment liquid. The first nozzle 15a dispenses the mixed liquid onto the upper surface W1 of the substrate W held by the substrate holder 13. The mixed liquid is obtained by adding the sublimable substance to the first treatment liquid, dehydrated by the dehydrating unit 23. The mixed liquid contains the first treatment liquid dehydrated by the dehydrating unit 23. The mixed liquid further contains the sublimable substance. Accordingly, when the first nozzle 15a dispenses the mixed liquid onto the upper surface W1 of the substrate W held by the substrate holder 13, the concentration of water in the mixed liquid is sufficiently low. Consequently, the substrate treating apparatus 1 can perform the substrate treating method of the second embodiment suitably. That is, the substrate treating apparatus 1 can dry substrates W appropriately.

The dehydrating unit 23 includes the absorber 24 and the separator 26. The absorber 24 absorbs water in the first treatment liquid. The separator 26 separates water from the first treatment liquid. Accordingly, the dehydrating unit 23 can dehydrate the first treatment liquid suitably.

The substrate treating apparatus 1 includes the first sensor 39 and the controller 10. The first sensor 39 measures a concentration of water in the first treatment liquid. The controller 10 obtains detection results of the first sensor 39. Accordingly, the controller 10 can monitor the concentration of water in the first treatment liquid suitably.

### 3. Third Embodiment

The following describes a substrate treating apparatus 1 according to a third embodiment with reference to drawings. Like numerals are used to identify like components which are the same as those in the first embodiment, and the components will not particularly be described.

The third embodiment has an outline of a substrate treating apparatus 1 and a construction of treating units 11 substantially same as those in the first embodiment. The following describes a construction of a mixed liquid adjusting unit 20 according to the third embodiment.

### 3-1. Construction of Mixed Liquid Adjusting Unit 20

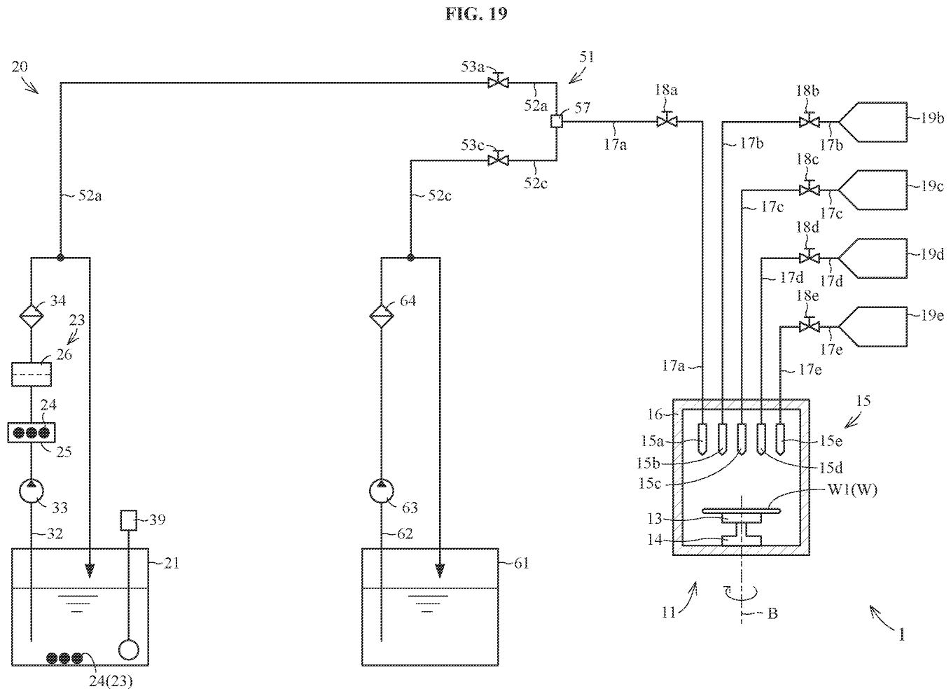

FIG. 19 shows the construction of a treating unit 11 and the mixed liquid adjusting unit 20 according to the third embodiment. In the third embodiment, the mixed liquid adjusting unit 20 dehydrates a mixed liquid. Accordingly, a first nozzle 15a dispenses the dehydrated mixed liquid. Moreover, the first nozzle 15a dispenses a surfactant together with the dehydrated mixed liquid.

A first tank 21 stores the mixed liquid. The mixed liquid contains the sublimable substance and the solvent.

A dehydrating unit 23 includes an absorber 24 and a separator 26. The absorber 24 is provided in the first tank 21 and on a circulation pipe 32.

The mixed liquid adjusting unit 20 includes a third tank 61 in addition to the first tank 21. The third tank 61 is in fluid communication with the first nozzle 15a. The third tank 61 is connected to the first nozzle 15a. The third tank 61 stores the surfactant. The surfactant is in the form of liquid.

The surfactant has hydrophobicity. The surfactant contains at least one selected from the chemical compounds a1) to a10) described above (except for one contained in the solvent stored in the first tank 21). None of the chemical compounds a1) to a10) is contained in both the solvent and the surfactant, respectively. For Example, when the chemical compound a1) is contained in the solvent, the chemical compound a1) is not contained in the surfactant. For Example, when the chemical compound a1) is contained in the surfactant, the chemical compound a1) is not contained in the solvent. The same also applies to the chemical compounds a2) to a10).

The mixed liquid adjusting unit 20 includes a circulation pipe 62, a pump 63, and a filter 64. The circulation pipe 62 is provided externally of the third tank 61. The circulation pipe 62 includes a first end communicating with the third tank 61, and a second end communicating with the third tank 61. The first end of the circulation pipe 62 is connected to the third tank 61. The second end of the circulation pipe 62 is connected to the third tank 61. The pump 63 is provided on the circulation pipe 62. The pump 63 feeds the surfactant. When the pump 63 actuates, the surfactant circulates in the third tank 61 and the circulation pipe 62. Specifically, the surfactant flows out from the third tank 61 to the circulation pipe 62 through the first end of the circulation pipe 62, and returns back to the third tank 61 from the circulation pipe 62 through the second end of the circulation pipe 62. The filter 64 is provided in the circulation pipe 62. The filter 64 filters the surfactant flowing in the circulation pipe 62. The filter 64 removes foreign substances from the surfactant.

A mixing unit 51 adds the surfactant to the dehydrated mixed liquid.

The mixing unit 51 includes a pipe 52c. The pipe 52c branches from the circulation pipe 62. The pipe 52c is connected to the circulation pipe 62. The pipe 52c is in fluid communication with the circulation pipe 62. The pipe 52c is also connected to a joint 57. The pipes 52a and 52c and the pipe 17a are in fluid communication with one another through the joint 57.

The circulation pipe 62 is in fluid communication with the first nozzle 15a. The circulation pipe 62 is connected to the first nozzle 15a via the pipes 52c and 17a. The third tank 61 is connected to the first nozzle 15a via the circulation pipe 62 and the pipes 52c and 17a.

A mixing unit 51 includes a valve 53c. The valve 53c is provided on the pipe 52c.

A controller 10 controls the pump 63 and the valve 53c, which illustration is omitted.

### 3-2. Operation Example of Mixed Liquid Adjusting Unit 20 and Treating Unit 11

Reference is made to FIG. 4. Similarly to the first embodiment, the substrate treating method according to the third embodiment includes a Step S1 and Steps S11 to S18. Operation in the Steps S11 to S14 and S16 to S18 are substantially common between the first embodiment and the third embodiment. Accordingly, description about the operation in the Steps S11 to S14 and S16 to S18 is to be omitted. The following describes operation in Steps S1 and S15.

Step S1: Dehydrating step

The dehydrating unit 23 dehydrates the mixed liquid. The dehydrating unit 23 dehydrates the mixed liquid in the first tank 21 and the circulation pipe 32. The dehydrating unit 23 dehydrates the mixed liquid with use of the absorber 24 and the separator 26. Specifically, the pump 33 operates. The mixed liquid circulates between the first tank 21 and the circulation pipe 32. The absorber 24 dehydrates the mixed liquid stored in the first tank 21. The absorber 24 also dehydrates the mixed liquid flowing in the circulation pipe 32. Specifically, the absorber 24 installed in the first tank 21 dehydrates the mixed liquid stored in the first tank 21. The absorber 24 installed in the circulation pipe 32 dehydrates the mixed liquid flowing in the circulation pipe 32. The separator 26 dehydrates the mixed liquid flowing in the circulation pipe 32. This causes dehydration of the mixed liquid stored in the first tank 21 and the mixed liquid flowing in the circulation pipe 32. A concentration of water in the mixed liquid in the first tank 21 becomes sufficiently low.

Step S15: Mixed liquid dispensing step

The pumps 33 and 63 operate. The valves 53a and 53c open. Moreover, the valve 18a opens. The dehydrated mixed liquid flows from the circulation pipe 32 to the pipe 52a. The surfactant flows from the circulation pipe 62 to the pipe 52c. The mixed liquid and the surfactant merge at the joint 57. The surfactant is added to the dehydrated mixed liquid. The dehydrated mixed liquid and the surfactant flow to the first nozzle 15a through the pipe 17a. The first nozzle 15a dispenses the dehydrate mixed liquid and the surfactant onto the upper surface W1 of the substrate W held by the substrate holder 13. More specifically, the first nozzle 15a dispenses a treatment liquid. The treatment liquid dispensed from the first nozzle 15a contains the dehydrated mixed liquid and the surfactant. The treatment liquid dispensed from the first nozzle 15a is a treatment liquid obtained by adding the surfactant to the mixed liquid. The mixed liquid and the surfactant are supplied onto the upper surface W1 of the substrate W. The mixed liquid and the surfactant replace a replacement solution on the substrate W. Then, the valves 18a, 53a, and 53c close. The first nozzle 15a stops dispensing the mixed liquid.

### 3-3. Effect of Third Embodiment

The third embodiment produces a similar effect to those of the first and second embodiments.

In the dehydrating step, the mixed liquid is dehydrated with use of the absorber 24 and the separator 26. Accordingly, the mixed liquid can be dehydrated more suitably in the dehydrating step.

The dehydrating step is executed in a tank (specifically, the first tank 21) that is in fluid communication with the first nozzle 15a and in a flow path (specifically, circulation pipe 32) that is in fluid communication with the first nozzle 15a. Specifically, the mixed liquid, stored in the first tank 21 that is in fluid communication with the first nozzle 15a, is dehydrated in the dehydrating step. Moreover, the mixed liquid, flowing in the circulation pipe 32 that is in fluid communication with the first nozzle 15a, is dehydrated in the dehydrating step. Accordingly, in the mixed liquid dispensing step where the mixed liquid is dispensed onto the upper surface W1 of the substrate W, the concentration of water in the mixed liquid is sufficiently low.

The absorber 24 is installed in the first tank 21. Accordingly, the dehydrating step is executed suitably in the first tank 21 that is in fluid communication with the first nozzle 15a. The absorber 24 and the separator 26 are each installed in the circulation pipe 32. Accordingly, the dehydrating step is executed suitably in the circulation pipe 32 that is in fluid communication with the first nozzle 15a.

The surfactant is supplied to the substrate W together with the mixed liquid in the mixed liquid dispensing step. In the mixed liquid dispensing step, the surfactant is supplied to the substrate W together with the mixed liquid, dehydrated in the dehydrating step. Here, affinity between the surfactant and the substrate W (e.g., projections W2) is relatively high. Consequently, the mixed liquid can be supplied onto the upper surface W1 of the substrate W more appropriately in the mixed liquid dispensing step. For example, the mixed liquid enters the recesses A more smoothly. For example, the mixed liquid removes the replacement solution from the substrate W more suitably. For example, the replacement solution can be prevented from remaining in recesses A in the form of liquid when the mixed liquid dispensing step completes. For example, the recesses A can be entirely filled only with the mixed liquid when the mixed liquid dispensing step completes. As a result, the substrate W can be dried more appropriately.

In the mixed liquid dispensing step, the treatment liquid containing the mixed liquid and the surfactant is dispensed onto the upper surface W1 of the substrate W. Consequently, the mixed liquid can be supplied onto the upper surface W1 of the substrate W much more appropriately in the mixed liquid dispensing step.

The surfactant has hydrophobicity. Accordingly, affinity between the surfactant and the substrate W (e.g., projections W2) is much higher. Consequently, the mixed liquid can be supplied onto the upper surface W1 of the substrate W more appropriately in the mixed liquid dispensing step.

The surfactant contains at least one selected from the chemical compounds a1) to a10) described above (except for one contained in the solvent). Consequently, the mixed liquid can be supplied onto the upper surface W1 of the substrate W more appropriately in the mixed liquid dispensing step.

### 4. Fourth Embodiment

The following describes a substrate treating apparatus 1 according to a fourth embodiment with reference to drawings. Like numerals are used to identify like components which are the same as those in the first embodiment, and the components will not particularly be described.

The fourth embodiment has an outline of a substrate treating apparatus 1 and a construction of treating units 11 substantially same as those in the first embodiment. The following describes a construction of a mixed liquid adjusting unit 20 according to the fourth embodiment.

### 4-1. Construction of Mixed Liquid Adjusting Unit 20

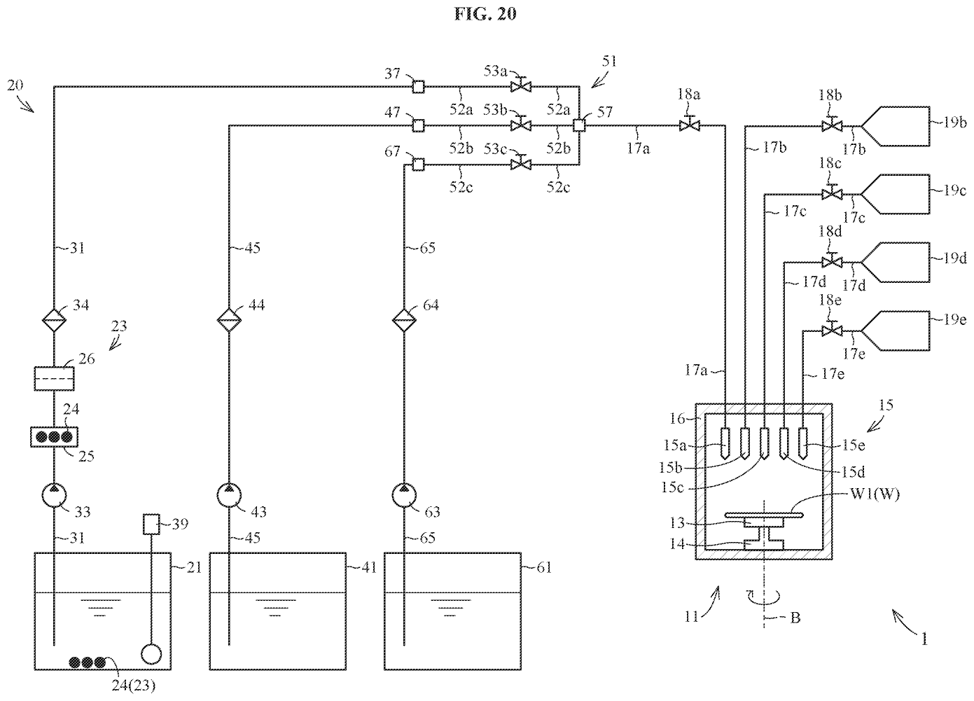

FIG. 20 shows the construction of the treating unit 11 and the mixed liquid adjusting unit 20 according to the fourth embodiment. In the fourth embodiment, the mixed liquid adjusting unit 20 dehydrates a first treatment liquid. Accordingly, a first nozzle 15a dispenses the dehydrated first treatment liquid. More specifically, the first nozzle 15a dispenses a mixed liquid obtained by adding a sublimable substance to the dehydrated first treatment liquid. Moreover, the first nozzle 15a dispenses a surfactant together with the mixed liquid.

A first tank 21 stores the first treatment liquid. In the fourth embodiment, the first tank 21 does not store the mixed liquid.

The first treatment liquid contains a solvent. The solvent contained in the first treatment liquid includes at least one selected from the chemical compounds a1) to a10) described above, for example. The first treatment liquid does not contain any sublimable substance, for example. The first treatment liquid consists of only a solvent, for example.

A dehydrating unit 23 includes an absorber 24 and a separator 26. The absorber 24 is provided in the first tank 21 and on a pipe 31. The separator 26 is provided on the pipe 31.

The pipe 31 is connected to a joint 37. The joint 37 is connected to a pipe 52a. The pipe 52a is connected to a joint 57. The joint 57 is connected to a pipe 17a.

The pipe 31 is in fluid communication with the first nozzle 15a. The pipe 31 is connected to the first nozzle 15a via the pipes 52a and 17a. The first tank 21 is in fluid communication with the first nozzle 15a. The first tank 21 is connected to the first nozzle 15a via the pipes 31, 52a, and 17a.

A second tank 41 stores a second treatment liquid.

The second treatment liquid contains a sublimable substance. The sublimable substance contains at least one selected from cyclohexanone oxime, camphor, naphthalene, and c-caprolactam, for example. The second treatment liquid contains a solvent, for example. The solvent contained in the second treatment liquid is of the same type as the solvent contained in the first treatment liquid, for example. The solvent contained in the second treatment liquid has, for example, a composition equal to a composition of the solvent contained in the first treatment liquid.

The mixed liquid adjusting unit 20 includes a pipe 45. The pipe 45 is in fluid communication with the second tank 41. The pipe 45 is connected to the second tank 41. The pipe 45 extends from the second tank 41 to the pipe 17a. A pump 43 is provided on the pipe 45. The pump 43 feeds the second treatment liquid from the second tank 41 to the pipe 45. A filter 44 is provided on the pipe 45. The filter 44 filters the second treatment liquid flowing in the pipe 45. The filter 44 removes foreign substances from the second treatment liquid.

The mixed liquid adjusting unit 20 includes a joint 47. The joint 47 is connected to the pipe 45. The joint 47 is also connected to a pipe 52b.

A third tank 61 stores the surfactant.

The surfactant is in the form of liquid. The surfactant has hydrophobicity. The surfactant contains at least one selected from the chemical compounds a1) to a10) described above (except for one contained in the solvent stored in the first tank 21). Neither the solvent nor the surfactant contains any of the chemical compounds a1) to a10).

The mixed liquid adjusting unit 20 includes a pipe 65. The pipe 65 is in fluid communication with the third tank 61. The pipe 65 is connected to the third tank 61. The pipe 65 extends from the third tank 61 to the pipe 17a. A pump 63 is provided on the pipe 65. The pump 63 feeds the surfactant from the third tank 61 to the pipe 65. A filter 64 is provided on the pipe 65. The filter 64 filters the surfactant flowing in the pipe 65. The filter 64 removes foreign substances from the surfactant.

The mixed liquid adjusting unit 20 includes a joint 67. The joint 67 is connected to the pipe 65. The joint 67 is also connected to a pipe 52c.

The pipes 52a, 52b, and 52c are in fluid communication with one another through the joint 57. A mixing unit 51 adds the second treatment liquid and the surfactant to the dehydrated first treatment liquid.

### 4-2. Operation Example of Mixed Liquid Adjusting Unit 20 and Treating Unit 11

Reference is made to FIG. 4. Similarly to the first embodiment, the substrate treating method according to the fourth embodiment includes a Step S1 and Steps S11 to S18. Operation in the Steps S11 to S14 and S16 to S18 are substantially common between the first embodiment and the fourth embodiment. Accordingly, description about the operation in the Steps S11 to S14 and S16 to S18 is to be omitted. The following describes operation in Steps S1 and S15.

Step S1: Dehydrating step

The dehydrating unit 23 dehydrates the first treatment liquid. The dehydrating unit 23 dehydrates the first treatment liquid in the first tank 21. The dehydrating unit 23 dehydrates the first treatment liquid with use of the absorber 24. The absorber 24 dehydrates the first treatment liquid stored in the first tank 21. Specifically, the absorber 24 installed in the first tank 21 dehydrates the first treatment liquid stored in the first tank 21. In such a manner as above, the first treatment liquid in the first tank 21 is dehydrated. A concentration of water in the first treatment liquid in the first tank 21 becomes sufficiently low.

Steps 51 and S15: Dehydrating step and mixed liquid dispensing step A pump 33 operates. A valve 53a opens. The pump 33 feeds the dehydrated first treatment liquid from the first tank 21 to the pipe 31. The first treatment liquid flows in the pipe 31. When the first treatment liquid flows in the pipe 31, the dehydrating unit 23 also dehydrates the first treatment liquid. Specifically, the absorber 24 provided in the pipe 31 dehydrates the first treatment liquid flowing in the pipe 31. Moreover, the separator 26 dehydrates the first treatment liquid flowing in the pipe 31. The dehydrated first treatment liquid flows from the pipe 31 to the mixing unit 51 (pipe 52a).

The pumps 43 and 63 operate. Valves 53b and 53c open. Moreover, a valve 18a opens. The pump 43 feeds the second treatment liquid from the second tank 41 to the mixing unit 51. The pump 63 feeds the surfactant from the third tank 61 to the mixing unit 51.

The second treatment liquid is added to the dehydrated first treatment liquid at the joint 57. That is, the sublimable substance is added to the dehydrated first treatment liquid. Accordingly, the mixed liquid is produced at the joint 57. Specifically, the mixed liquid is produced at the joint 57 by adding the sublimable substance to the dehydrated first treatment liquid. Moreover, the surfactant is added to the mixed liquid at the joint 57. The mixed liquid and the surfactant flow to the first nozzle 15a through the pipe 17a. The first nozzle 15a dispenses the mixed liquid and the surfactant onto the upper surface W1 of the substrate W held by the substrate holder 13. More specifically, the first nozzle 15a dispenses a treatment liquid containing the mixed liquid and the surfactant. The mixed liquid and the surfactant are supplied onto the upper surface W1 of the substrate W. The mixed liquid and the surfactant replace the replacement solution on the substrate W. Then, the valves 18a, 53a, 53b and 53c close. The first nozzle 15a stops dispensing the mixed liquid.

### 4-3. Effect of Fourth Embodiment

The fourth embodiment produces a similar effect to those of the first to third embodiments.

In the dehydrating step, the first treatment liquid is dehydrated with use of the absorber 24 and the separator 26. Accordingly, the first treatment liquid can be dehydrated more suitably in the dehydrating step.

The dehydrating step is executed in a tank (specifically, the first tank 21) that is in fluid communication with the first nozzle 15a and in a flow path (specifically, pipe 31) that is in fluid communication with the first nozzle 15a. Specifically, the first treatment liquid, stored in the first tank 21 that is in fluid communication with the first nozzle 15a, is dehydrated in the dehydrating step. Furthermore, the first treatment liquid, flowing in the pipe 31 that is in fluid communication with the first nozzle 15a, is dehydrated in the dehydrating step. In the mixed liquid dispensing step, the mixed liquid is dispensed onto the upper surface W1 of the substrate W. The mixed liquid contains the first treatment liquid dehydrated in the dehydrating step. Accordingly, in the mixed liquid dispensing step where the mixed liquid is dispensed onto the upper surface W1 of the substrate W, the concentration of water in the mixed liquid is sufficiently low.

The absorber 24 is installed in the first tank 21. Accordingly, the dehydrating step is executed suitably in the first tank 21 that is in fluid communication with the first nozzle 15a. The absorber 24 and the separator 26 are each installed in the pipe 31. Accordingly, the dehydrating step is executed suitably in the pipe 31 that is in fluid communication with the first nozzle 15a.

The surfactant is supplied to the substrate W together with the mixed liquid in the mixed liquid dispensing step. Consequently, the mixed liquid can be supplied onto the upper surface W1 of the substrate W more appropriately in the mixed liquid dispensing step.

This invention is not limited to the foregoing examples, but may be modified as follows.

(1) In the first embodiment, the mixed liquid is dehydrated with use of the absorber 24 in the dehydrating step. In the third embodiment, the mixed liquid is dehydrated with use of the absorber 24 and the separator 26 in the dehydrating step. However, the present invention is not limited to this. The mixed liquid may be dehydrated with use of at least either the absorber 24 or the separator 26 in the dehydrating step.

(2) In the second and fourth embodiments, the first treatment liquid is dehydrated with use of the absorber 24 and the separator 26 in the dehydrating step. However, the present invention is not limited to this. The first treatment liquid may be dehydrated with use of at least either the absorber 24 or the separator 26 in the dehydrating step.

(3) In the second and fourth embodiments, the mixed liquid is obtained by adding the second treatment liquid containing the sublimable substance to the first treatment liquid. That is, the sublimable substance is added to the first treatment liquid in a state where the sublimable substance is dissolved in the second treatment liquid. However, the present invention is not limited to this. The mixed liquid can be obtained without using the second treatment liquid. The sublimable substance may be added to the first treatment liquid without using the second treatment liquid. The sublimable substance may itself be added to the first treatment liquid. The sublimable substance (solid) may be added to the first treatment liquid. The sublimable substance may be dissolved in the first treatment liquid.

(4) In the first and third embodiments, the mixed liquid does not contain the surfactant. The mixed liquid stored in the first tank 21 consists of only the solvent and the sublimable substance, for example. However, the present invention is not limited to this. The mixed liquid may include the surfactant. The mixed liquid stored in the first tank 21 may contain the solvent, the sublimable substance, and the surfactant, for example. According to this modification, the mixed liquid can be supplied onto the upper surface W1 of the substrate W more appropriately in the mixed liquid dispensing step.

(5) In the second and fourth embodiments, the first treatment liquid does not contain the surfactant. The first treatment liquid stored in the first tank 21 consists of by only the solvent, for example. However, the present invention is not limited to this. The first treatment liquid may include the surfactant. The first treatment liquid stored in the first tank 21 may contain the solvent and the surfactant, for example. According to this modification, the mixed liquid can be supplied onto the upper surface W1 of the substrate W more appropriately in the mixed liquid dispensing step.

(6) In the second and fourth embodiments, the second treatment liquid does not contain the surfactant. The second treatment liquid stored in the second tank 41 consists of only the sublimable substance and the solvent, for example. However, the present invention is not limited to this. The second treatment liquid may contain the surfactant. The second treatment liquid stored in the second tank 41 may contain the sublimable substance, the solvent, and the surfactant, for example. The second treatment liquid stored in the second tank 41 may contain the sublimable substance and the surfactant, for example. The second treatment liquid stored in the second tank 41 may not contain the solvent, for example. According to this modification, the mixed liquid can be supplied onto the upper surface W1 of the substrate W more appropriately in the mixed liquid dispensing step.

(7) It is preferred that the surfactant has hydrophobicity even when the surfactant is contained in at least any of the mixed liquid, the first treatment liquid, and the second treatment liquid. It is preferred that the surfactant contains at least one of the chemical compounds a1) to a10) described above (except for one contained in the solvent) even when the surfactant is contained in at least any of the mixed liquid, the first treatment liquid, and the second treatment liquid.

(8) In the first to fourth embodiments, the substrate treating method includes the chemical liquid dispensing step, the rinse liquid dispensing step, and the replacement solution dispensing step. However, the present invention is not limited to this. For example, at least any of the chemical liquid dispensing step, the rinse liquid dispensing step, and the replacement solution dispensing step may be omitted. For example, all the chemical liquid dispensing step, the rinse liquid dispensing step, and the replacement solution dispensing step may be omitted.

(9) In the first to fourth embodiments, a liquid (e.g., replacement solution) exists on the upper surface W1 of the substrate W when the mixed liquid dispensing step is executed. That is, the mixed liquid is dispensed to a non-dried substrate W in the mixed liquid dispensing step. However, the present invention is not limited to this. For example, a liquid (e.g., replacement solution) may not exist on the upper surface W1 of the substrate W when the mixed liquid dispensing step is executed. For example, the mixed liquid may be dispensed to a dried substrate W in the mixed liquid dispensing step.

(10) In the first to fourth embodiments, the mixed liquid removes the replacement solution from the upper surface W1 of the substrate W in the mixed liquid dispensing step. However, the present invention is not limited to this. For example, the mixed liquid may clean the upper surface W1 of the substrate W in the mixed liquid dispensing step. For example, the mixed liquid may remove foreign substances attached to the upper surface W1 of the substrate W in the mixed liquid dispensing step. For example, the mixed liquid may dissolve foreign substances attached to the upper surface W1 of the substrate W in the mixed liquid dispensing step. The foreign substances are, for example, resist residual.

(11) In the first to fourth embodiments, the dry gas is not supplied to the upper surface W1 of the substrate W in the solidified film forming step. However, the present invention is not limited to this. The dry gas may be supplied to the upper surface W1 of the substrate W in the solidified film forming step. The dry gas may be supplied to the mixed liquid on the substrate W in the solidified film forming step. This can form the solidified film on the upper surface W1 of the substrate W effectively in the solidified film forming step.

(12) In the first to fourth embodiments, the substrate treating apparatus 1 includes the first sensor 39. However, the present invention is not limited to this. The first sensor 39 is omittable.

(13) In the first to fourth embodiments, the first sensor 39 is provided in the first tank 21. However, the present invention is not limited to this. For example, the first sensor 39 may be provided in the pipe 31 or the circulation pipe 32. For example, the first sensor 39 may be provided at a position apart from the first tank 21, the pipe 31, and the circulation pipe 32. For example, the first sensor 39 may be provided at a position that is not in communication with the first tank 21, the pipe 31, and the circulation pipe 32.

(14) The first to fourth embodiments and each of the modified embodiments described in paragraphs (1) to (13) above may be further varied as appropriate by replacing or combining their constructions with the constructions of the other modified embodiments.

The present invention may be embodied in other specific forms without departing from the spirit or essential attributes thereof and, accordingly, reference should be made to the appended claims, rather than to the foregoing specification, as indicating the scope of the invention.

What is claimed is:

1. A substrate treating method for treating the substrate, the substrate treating method comprising:
a dehydrating step of dehydrating a mixed liquid containing a sublimable substance and a solvent;
a dispensing step of dispensing the mixed liquid, dehydrated in the dehydrating step, onto an upper surface of the substrate;
a solidified film forming step of forming a solidified film containing the sublimable substance on the upper surface of the substrate by evaporating the solvent from the mixed liquid on the upper surface of the substrate; and
a sublimation step of sublimating the solidified film.

2. The substrate treating method according to claim 1, wherein
a percent concentration of mass of water contained in the mixed liquid is made 1.2 wt % or less in the dehydrating step.

3. The substrate treating method according to claim 1, wherein
the mixed liquid is dehydrated in the dehydrating step with use of at least either an absorber configured to absorb water in the mixed liquid or a separator configured to separate water from the mixed liquid.

4. The substrate treating method according to claim 1, wherein
the mixed liquid is dispensed onto the upper surface of the substrate in the dispensing step by a dispensing unit, and
the dehydrating step is performed in either a flow path communicating with the dispensing unit or a tank communicating with the dispensing unit.

5. The substrate treating method according to claim 1, wherein
the solvent contains at least one selected from chemical compounds a1) to a10):
a1) acetone;
a2) methanol;
a3) ethanol;
a4) isopropyl alcohol;
a5) tert-butanol;
a6) 1-propanol;
a7) isobutanol;
a8) 1-ethoxy-2-propanol;
a9) 1-butanol; and
a10) propylene glycol monomethyl ether acetate.

6. The substrate treating method according to claim 1, wherein
the sublimable substance contains at least one selected from:
cyclohexanone oxime;
camphor;
naphthalene; and
ε-caprolactam.

7. The substrate treating method according to claim 1, wherein
dry gas is supplied to the solidified film in the sublimation step.

8. The substrate treating method according to claim 1, wherein
the mixed liquid further contains a surfactant.

9. The substrate treating method according to claim 8, wherein
the surfactant has hydrophobicity.

10. The substrate treating method according to claim 1, wherein
a surfactant is supplied to the substrate together with the mixed liquid in the dispensing step.

11. The substrate treating method according to claim 1, wherein
the substrate has a pattern formed on the upper surface of the substrate.

12. A substrate treating method for treating the substrate, the substrate treating method comprising:
a dehydrating step of dehydrating a first treatment liquid containing a solvent;
a dispensing step of dispensing a mixed liquid, obtained by adding a sublimable substance to the first treatment liquid dehydrated in the dehydrating step, onto an upper surface of the substrate;
a solidified film forming step of forming a solidified film containing the sublimable substance on the upper surface of the substrate by evaporating the solvent from the mixed liquid on the upper surface of the substrate; and
a sublimation step of sublimating the solidified film.

13. The substrate treating method according to claim 12, wherein
a percent concentration of mass of water contained in the first treatment liquid is made 1.2 wt % or less in the dehydrating step.

14. The substrate treating method according to claim 12, wherein
the first treatment liquid is dehydrated in the dehydrating step with use of at least either an absorber configured to absorb water in the first treatment liquid or a separator configured to separate water from the first treatment liquid.

15. The substrate treating method according to claim 12, wherein
the mixed liquid is dispensed onto the upper surface of the substrate in the dispensing step by a dispensing unit, and
the dehydrating step is performed in either a flow path communicating with the dispensing unit or a tank communicating with the dispensing unit.

16. The substrate treating method according to claim 12, wherein
the solvent contains at least one selected from chemical compounds a1) to a10):
a1) acetone;
a2) methanol;
a3) ethanol;
a4) isopropyl alcohol;
a5) tert-butanol;
a6) 1-propanol;
a7) isobutanol;
a8) 1-ethoxy-2-propanol;
a9) 1-butanol; and
a10) propylene glycol monomethyl ether acetate.

17. The substrate treating method according to claim 12, wherein the sublimable substance contains at least one selected from:
cyclohexanone oxime;
camphor;
naphthalene; and
ε-caprolactam.

18. The substrate treating method according to claim 12, wherein
the mixed liquid further contains a surfactant.

19. The substrate treating method according to claim 12, wherein
a surfactant is supplied to the substrate together with the mixed liquid in the dispensing step.

20. The substrate treating method according to claim 12, wherein
the first treatment liquid further contains a surfactant.
